(19) United States
(12) Patent Application Publication
(10) Pub. No.: US 2016/0190487 A1
(43) Pub. Date: Jun. 30, 2016

(54) MATERIAL FOR ORGANIC ELECTROLUMINESCENT DEVICE AND ORGANIC ELECTROLUMINESCENT DEVICE INCLUDING THE SAME

(71) Applicant: SAMSUNG DISPLAY CO., LTD., Yongin-si (KR)

(72) Inventors: Nobutaka Akashi, Yokohama (JP); Masatsugu Ueno, Yokohama (JP)

(21) Appl. No.: 14/941,499

(22) Filed: Nov. 13, 2015

(30) Foreign Application Priority Data
Dec. 25, 2014 (JP) 2014-263327

(51) Int. Cl. H01L 51/00; C07F 7/08

(52) U.S. Cl. CPC H01L 51/0094; C07F 7/0816; H01L 51/5056

(57) ABSTRACT

The material for an organic electroluminescent device includes a monoamine derivative represented by Formula 1. An organic electroluminescent device including the material can exhibit low driving voltage and improved emission efficiency. The material can be included in at least one layer positioned between an emission layer and an anode of the organic electroluminescent device.

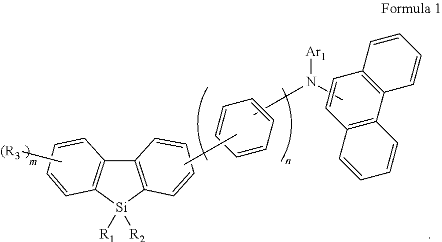

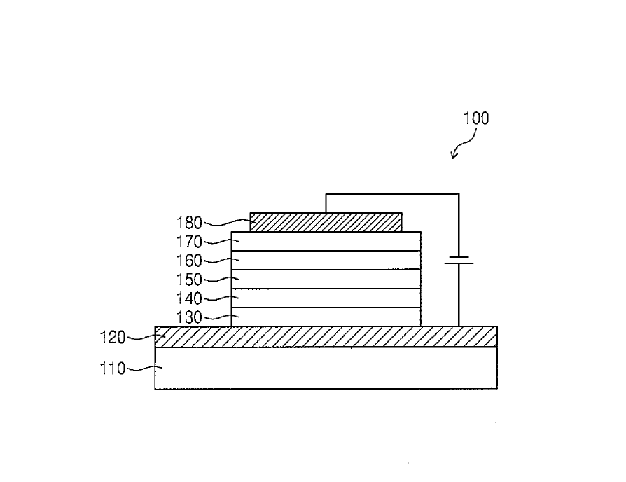

### CROSS-REFERENCE TO RELATED APPLICATIONS

This application claims priority to and the benefit of Japanese Patent Application No. 2014-263327, filed on Dec. 25, 2014, the entire content of which is hereby incorporated by reference.

### BACKGROUND

1. Field

One or more aspects of embodiments of the present disclosure herein relate to a material for an organic electroluminescent device and an organic electroluminescent device including the same.

2. Description of the Related Art

In recent years, there has been active development of organic electroluminescent (EL) displays as image displays. For example, organic EL devices which are self-luminescent devices used in organic EL displays are being actively developed.

An organic EL device may have a structure including, for example, an anode, a hole transport layer positioned on the anode, an emission layer positioned on the hole transport layer, an electron transport layer positioned on the emission layer, and a cathode positioned on the electron transport layer.

In the organic EL device, holes and electrons injected from the anode and the cathode recombine in the emission layer to generate excitons, where light is emitted via the transition of the excitons to a ground state. As a hole transport material or a hole injection material used in the hole transport layer or the hole injection layer, an amine derivative including a carbazolyl group is known in the art.

However, an organic EL device using such known amine derivative as a hole transport material may exhibit low driving voltage and low emission efficiency. Thus, there is a need for a material capable of decreasing the driving voltage of an organic EL device and improving emission efficiency.

### SUMMARY

One or more aspects of embodiments of the present disclosure are directed towards a novel and improved material for an organic EL device, capable of decreasing the driving voltage and improving emission efficiency of an organic EL device, and an organic EL device including the same.

An embodiment of the present disclosure provides a material for an organic EL device, the material including a monoamine derivative represented by the following Formula 1:

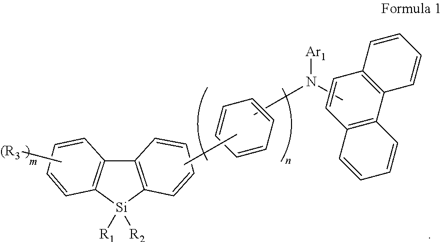

In Formula 1, An may be selected from a substituted or unsubstituted aryl group having 6 to 30 carbon atoms for forming a ring, and a substituted or unsubstituted heteroaryl group having 3 to 30 carbon atoms for forming a ring; R₁ to R₃ may be each independently selected from hydrogen, deuterium, a halogen atom, a substituted or unsubstituted alkyl group having 1 to 30 carbon atoms, a substituted or unsubstituted aryl group having 6 to 30 carbon atoms for forming a ring, and a substituted or unsubstituted heteroaryl group having 3 to 30 carbon atoms for forming a ring; and n and m may be each independently an integer selected from 0 to 4.

In this regard, the driving voltage of the organic EL device may decrease, and the emission efficiency thereof may be improved.

In some embodiments, Ar₁ may be selected from a substituted or unsubstituted biphenyl group, a substituted or unsubstituted phenanthrenyl group, and a substituted or unsubstituted dibenzofuranyl group.

In this regard, the driving voltage of the organic EL device may decrease, and the emission efficiency thereof may be improved.

In an embodiment of the present disclosure, an organic EL device includes an anode, a cathode, an emission layer between the anode and the cathode, and at least one layer between the anode and the emission layer, the at least one layer including the material for an organic EL device.

In this regard, the driving voltage of the organic EL device may decrease, and the emission efficiency thereof may be improved.

In some embodiments, the material for an organic EL device may be included in a layer positioned between the anode and the emission layer and more adjacent to the emission layer than to the anode.

In this regard, the driving voltage of the organic EL device may decrease, and the emission efficiency thereof may be improved.

### BRIEF DESCRIPTION OF THE DRAWINGS

The accompanying drawing is included to provide a further understanding of the present disclosure, and is incorporated in and constitutes a part of this specification. The drawing illustrates example embodiments of the present disclosure and, together with the description, serves to explain principles of the present disclosure. The drawing is a cross-sectional view illustrating the schematic configuration of an organic EL device according to one or more embodiments of the present disclosure.

### DETAILED DESCRIPTION

Hereinafter, example embodiments of the present disclosure will be described in more detail with reference to the accompanying drawing. In the description and drawing, elements having substantially the same function are designated by the same reference numerals, and repeated explanation thereof will not be provided.

### 1. Configuration of Material for Organic EL Device

According to one or more embodiments of the present disclosure, a material for an organic EL device may lower the driving voltage of the organic EL device and improve emission efficiency. When the material for an organic EL device is used (utilized) as a hole transport material, the driving voltage of the organic EL device including the material may be lowered, and emission efficiency thereof may be improved. First, the configuration of the material for an organic EL device according to embodiments of the present disclosure will be explained. The material for an organic EL device according to embodiments of the present disclosure includes a monoamine compound represented by the following Formula 1. Herein, “monoamine compound” refers to a compound including one amine moiety.

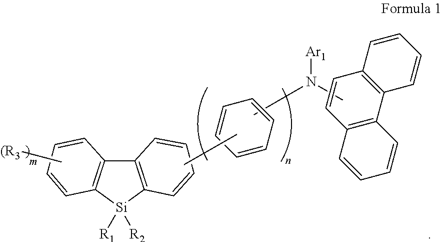

In Formula 1, Ar₁ may be selected from a substituted or unsubstituted aryl group having 6 to 30 carbon atoms for forming a ring, and a substituted or unsubstituted heteroaryl group having 3 to 30 carbon atoms for forming a ring. In some embodiments, Ar₁ may be selected from a substituted or unsubstituted biphenyl group, phenanthrenyl group, and dibenzofuranyl group. As used herein, the statement “atoms for forming a ring” may refer to “ring-forming atoms.”

In Formula 1, Ar₁ may be selected from a substituted or unsubstituted phenyl group, biphenyl group, terphenyl group, naphthyl group, anthryl group, phenanthrenyl group, fluorenyl group, indenyl group, pyrenyl group, fluoranthenyl group, triphenylenyl group, perylenyl group, naphthylphenyl group, biphenylenyl group, etc.

In some embodiments, Ar₁ in Formula 1 may be selected from a substituted or unsubstituted pyridyl group, quinolyl group, isoquinolyl group, indolyl group, benzoxazolyl group, benzothiazolyl group, quinoxalyl group, benzoimidazolyl group, indazolyl group, carbazolyl group, benzofuranyl group, isobenzofuranyl group, dibenzofuranyl group, phenoxazinyl group, benzothiophenyl group, dibenzothiophenyl group, etc.

One or more substituents of the aryl group and/or the heteroaryl group forming, for example, Ar₁, an alkyl group (e.g., a methyl group, an ethyl group, etc.), an alkenyl group (e.g., a vinyl group, etc.), a halogen atom (e.g., a fluorine atom, a chlorine atom, etc.), a silyl group (e.g., a trimethylsilyl group, etc.), a cyano group, an alkoxy group (e.g., a methoxy group, a butoxy group, etc.), a nitro group, a hydroxyl group, a thiol group, etc. may be used other than the aryl group. However, in some embodiments, the substituent may be a functional group other than a vinyl group, an indolyl group or a triphenylenyl group, in consideration of thermal stability. For example, the substituent may be substituted with the same functional group as the substituent.

In Formula 1, R₁ to R₃ may be each independently selected from hydrogen, deuterium, a halogen atom, a substituted or unsubstituted alkyl group having 1 to 30 carbon atoms, a substituted or unsubstituted aryl group having 6 to 30 carbon atoms for forming a ring, and a substituted or unsubstituted heteroaryl group having 3 to 30 carbon atoms for forming a ring. For example, R₁, R₂ and R₃ may be a phenyl group. The combination position (e.g., coupling position) of R₃ with a dibenzosilolyl group in Formula 1 is not limited, and may be position 2 or 3 of the dibenzosilolyl group.

The halogen atom may be selected from a fluorine atom, a chlorine atom, a bromine atom and an iodine atom.

The alkyl group having 1 to 30 carbon atoms may include a linear alkyl group (e.g., a methyl group, an ethyl group, a propyl group, a butyl group, an octyl group, a decyl group, a pentadecyl group, etc.) or a branched alkyl group (e.g., a t-butyl group, etc.).

As the substituted or unsubstituted aryl group having 6 to 30 carbon atoms for forming a ring and/or the substituted or unsubstituted heteroaryl group having 3 to 30 carbon atoms for forming a ring, forming, for example, any of R₁ to R₃, the same substituent as Ar₁ may be used. In some embodiments, the aryl group and/or the heteroaryl group forming R₁ to R₃ may be substituted with the same substituent as the substituent of the aryl group and/or the heteroaryl group forming Ar₁.

In some embodiments, n and m may be each independently an integer selected from 0 to 4. When m is equal to or greater than 2, a plurality of R₃(s) may be the same as or different from each other.

According to embodiments of the present disclosure, the emission efficiency of the organic EL device including the monoamine derivative represented by Formula 1 may be further improved when an emission layer of the organic EL device includes a blue emission material or a green emission material.

The material for an organic EL device including the monoamine derivative represented by Formula 1 according to embodiments of the present disclosure may be included in at least one layer positioned between an emission layer and an anode in the organic EL device. In some embodiments, the material for an organic EL device may be included in a layer positioned between an emission layer and an anode and more adjacent to the emission layer than to the anode (e.g., adjacent to the emission layer) in the organic EL device. For example, the material for an organic EL device including the monoamine derivative represented by Formula 1 may be included in the hole transport layer and the hole injection layer of the organic EL device. However, the layer including the monoamine derivative represented by Formula 1 in the organic EL device is not limited thereto. For example, the monoamine derivative represented by Formula 1 may be included in one organic layer positioned between the anode and the cathode of the organic EL device.

An organic EL device using the material for an organic EL device having the above-mentioned configuration may have decreased driving voltage, and in some embodiments, improved emission efficiency. The monoamine derivative according to embodiments of the present disclosure may include at least one of the following Compounds 1 to 48, but is not limited thereto:

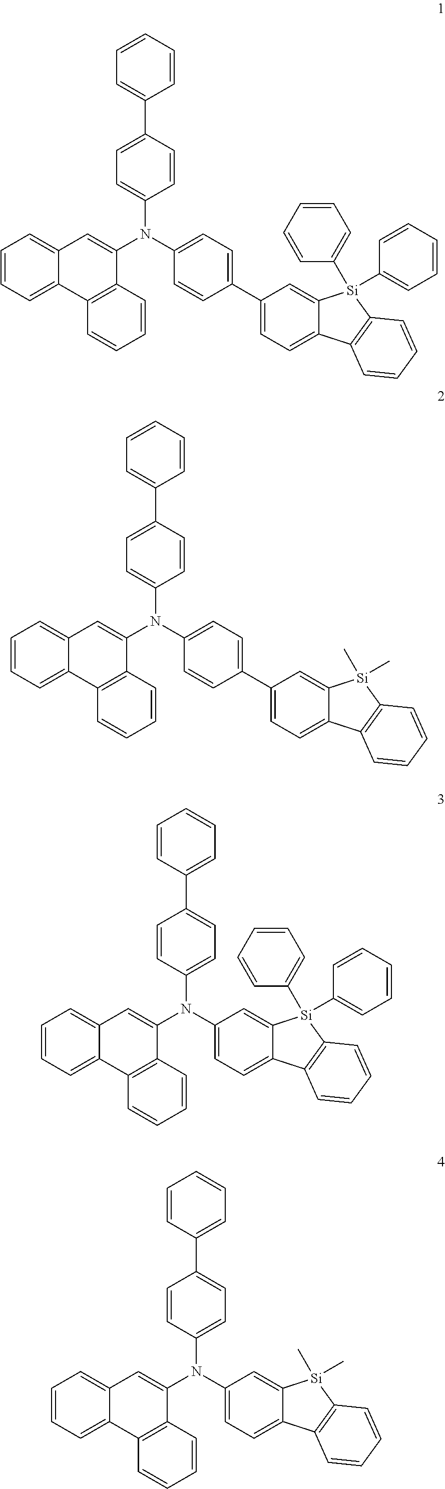 [SMILES: c1ccc(-c2ccc(N(c3ccc(-c4ccc5c(c4)[Si](c4ccccc4)(c4ccccc4)c4ccccc4-5)cc3)c3cc4ccccc4c4ccccc34)cc2)cc1 ; C[Si]1(C)c2ccccc2-c2ccc(-c3ccc(N(c4ccc(-c5ccccc5)cc4)c4cc5ccccc5c5ccccc45)cc3)cc21 ; c1ccc(-c2ccc(N(c3ccc4c(c3)[Si](c3ccccc3)(c3ccccc3)c3ccccc3-4)c3cc4ccccc4c4ccccc34)cc2)cc1 ; C[Si]1(C)c2ccccc2-c2ccc(N(c3ccc(-c4ccccc4)cc3)c3cc4ccccc4c4ccccc34)cc21]

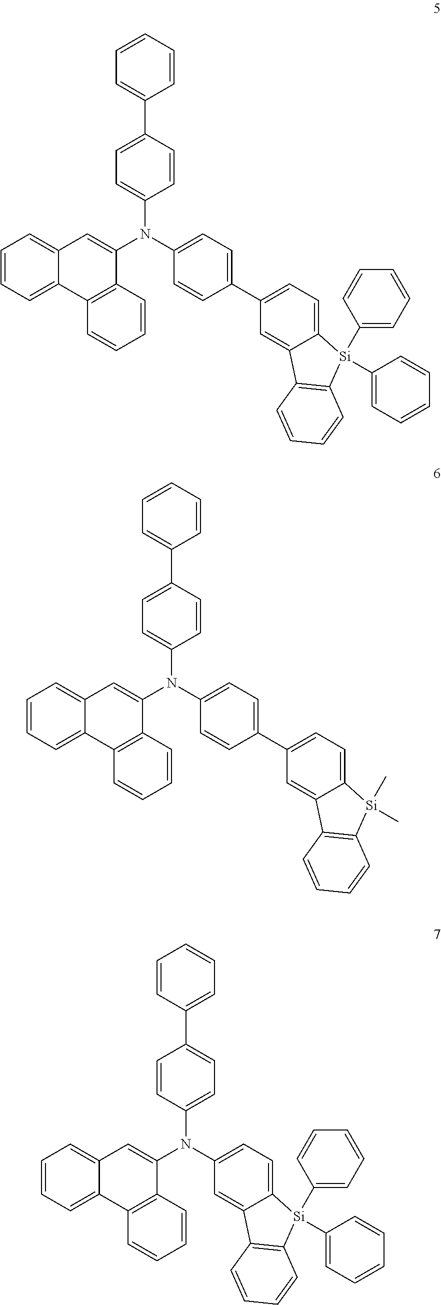 [SMILES: c1ccc(-c2ccc(N(c3ccc(-c4ccc5c(c4)-c4ccccc4[Si]5(c4ccccc4)c4ccccc4)cc3)c3cc4ccccc4c4ccccc34)cc2)cc1 ; C[Si]1(C)c2ccccc2-c2cc(-c3ccc(N(c4ccc(-c5ccccc5)cc4)c4cc5ccccc5c5ccccc45)cc3)ccc21 ; c1ccc(-c2ccc(N(c3ccc4c(c3)-c3ccccc3[Si]4(c3ccccc3)c3ccccc3)c3cc4ccccc4c4ccccc34)cc2)cc1]

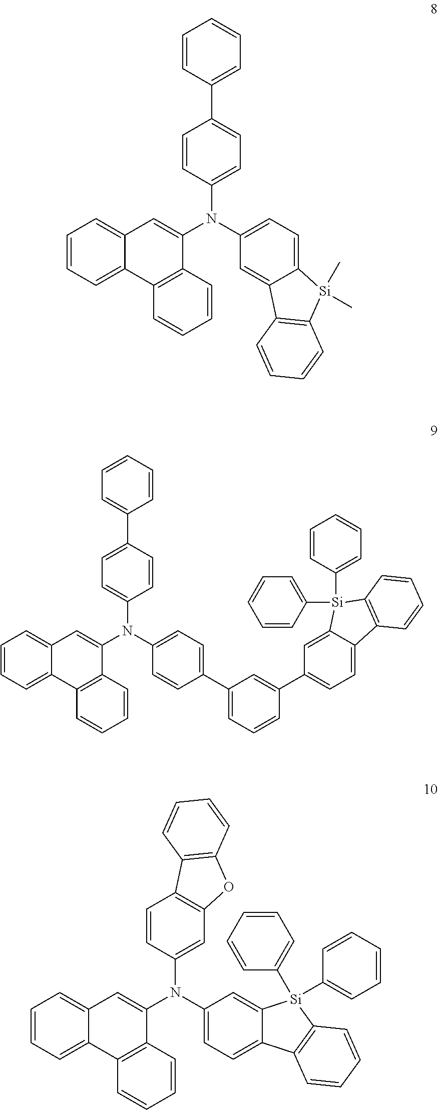 [SMILES: C[Si]1(C)c2ccccc2-c2cc(N(c3ccc(-c4ccccc4)cc3)c3cc4ccccc4c4ccccc34)ccc21 ; c1ccc(-c2ccc(N(c3ccc(-c4cccc(-c5ccc6c(c5)[Si](c5ccccc5)(c5ccccc5)c5ccccc5-6)c4)cc3)c3cc4ccccc4c4ccccc34)cc2)cc1 ; c1ccc([Si]2(c3ccccc3)c3ccccc3-c3ccc(N(c4ccc5c(c4)oc4ccccc45)c4cc5ccccc5c5ccccc45)cc32)cc1]

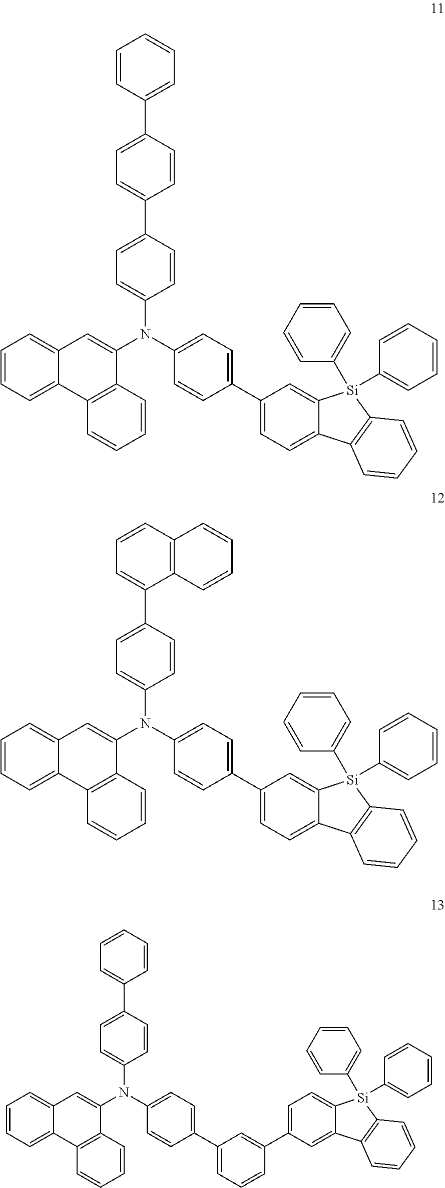 [SMILES: c1ccc(-c2ccc(-c3ccc(N(c4ccc(-c5ccc6c(c5)[Si](c5ccccc5)(c5ccccc5)c5ccccc5-6)cc4)c4cc5ccccc5c5ccccc45)cc3)cc2)cc1 ; c1ccc([Si]2(c3ccccc3)c3ccccc3-c3ccc(-c4ccc(N(c5ccc(-c6cccc7ccccc67)cc5)c5cc6ccccc6c6ccccc56)cc4)cc32)cc1 ; c1ccc(-c2ccc(N(c3ccc(-c4cccc(-c5ccc6c(c5)-c5ccccc5[Si]6(c5ccccc5)c5ccccc5)c4)cc3)c3cc4ccccc4c4ccccc34)cc2)cc1]

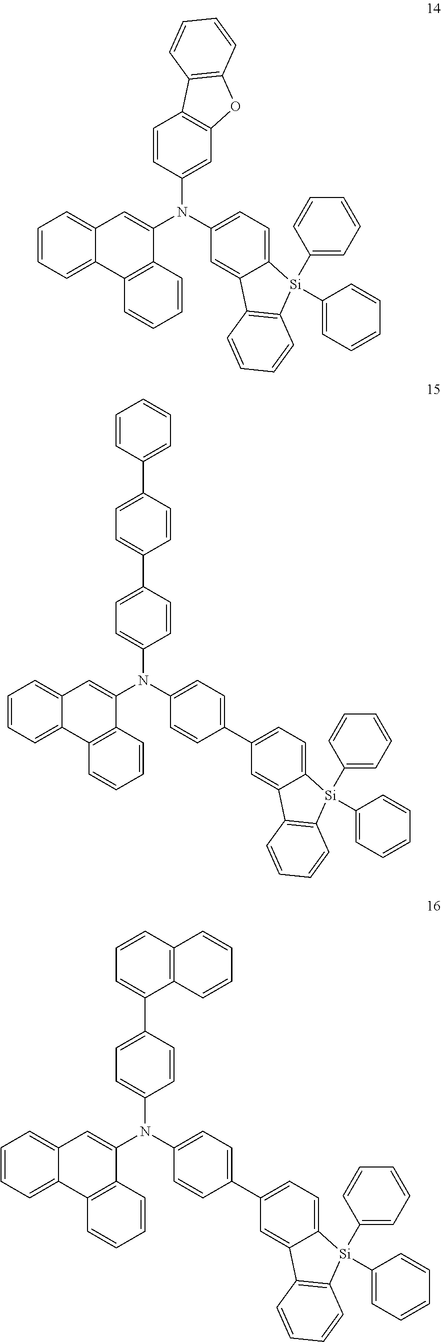 [SMILES: c1ccc([Si]2(c3ccccc3)c3ccccc3-c3cc(N(c4ccc5c(c4)oc4ccccc45)c4cc5ccccc5c5ccccc45)ccc32)cc1 ; c1ccc(-c2ccc(-c3ccc(N(c4ccc(-c5ccc6c(c5)-c5ccccc5[Si]6(c5ccccc5)c5ccccc5)cc4)c4cc5ccccc5c5ccccc45)cc3)cc2)cc1 ; c1ccc([Si]2(c3ccccc3)c3ccccc3-c3cc(-c4ccc(N(c5ccc(-c6cccc7ccccc67)cc5)c5cc6ccccc6c6ccccc56)cc4)ccc32)cc1]

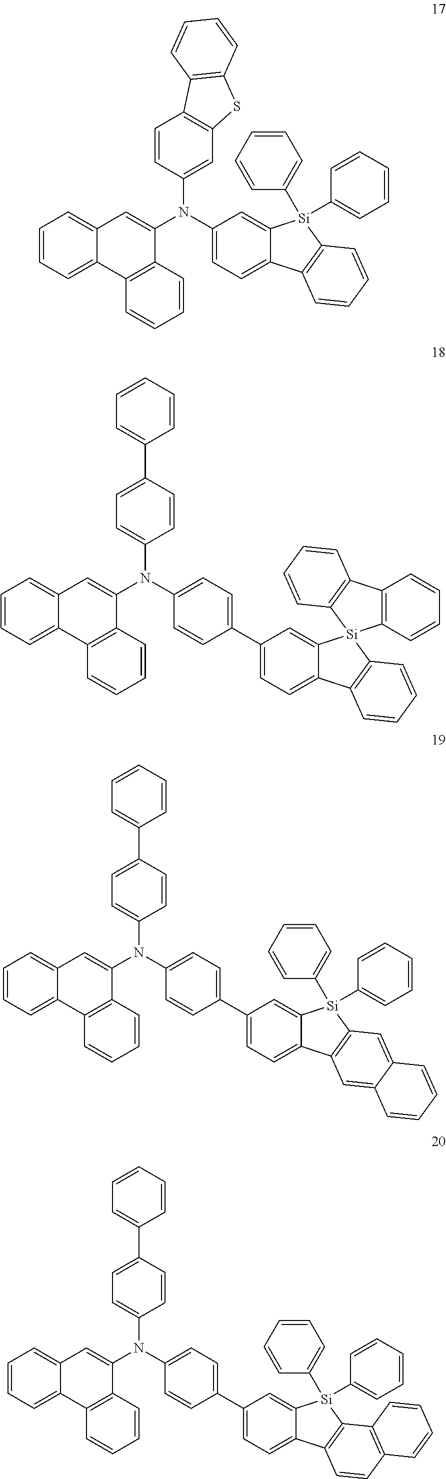 [SMILES: c1ccc([Si]2(c3ccccc3)c3ccccc3-c3ccc(N(c4ccc5c(c4)sc4ccccc45)c4cc5ccccc5c5ccccc45)cc32)cc1 ; c1ccc(-c2ccc(N(c3ccc(-c4ccc5c(c4)[Si]4(c6ccccc6-c6ccccc64)c4ccccc4-5)cc3)c3cc4ccccc4c4ccccc34)cc2)cc1 ; c1ccc(-c2ccc(N(c3ccc(-c4ccc5c(c4)[Si](c4ccccc4)(c4ccccc4)c4cc6ccccc6cc4-5)cc3)c3cc4ccccc4c4ccccc34)cc2)cc1 ; c1ccc(-c2ccc(N(c3ccc(-c4ccc5c(c4)[Si](c4ccccc4)(c4ccccc4)c4c-5ccc5ccccc45)cc3)c3cc4ccccc4c4ccccc34)cc2)cc1]

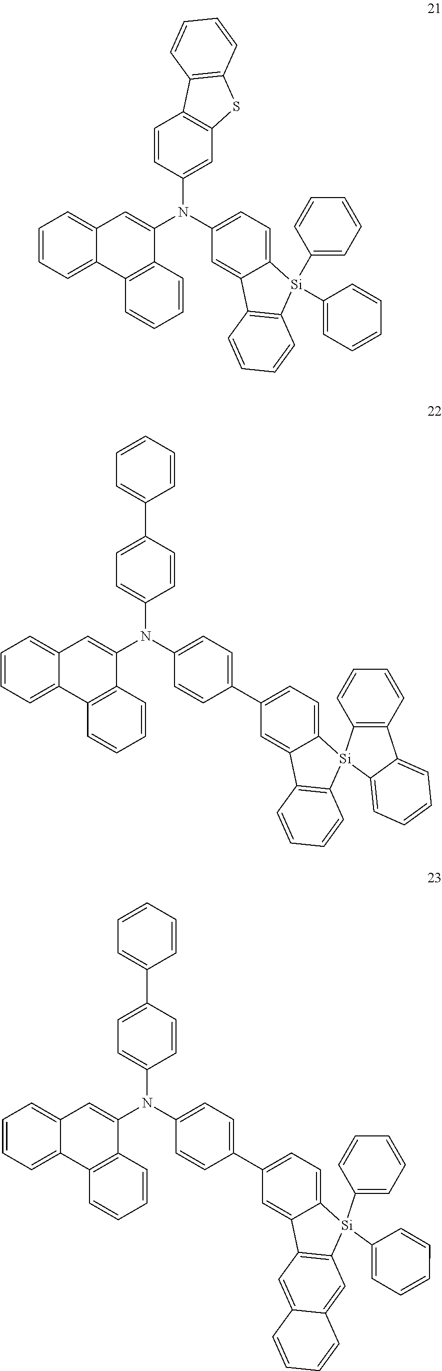 [SMILES: c1ccc([Si]2(c3ccccc3)c3ccccc3-c3cc(N(c4ccc5c(c4)sc4ccccc45)c4cc5ccccc5c5ccccc45)ccc32)cc1 ; c1ccc(-c2ccc(N(c3ccc(-c4ccc5c(c4)-c4ccccc4[Si]54c5ccccc5-c5ccccc54)cc3)c3cc4ccccc4c4ccccc34)cc2)cc1 ; c1ccc(-c2ccc(N(c3ccc(-c4ccc5c(c4)-c4cc6ccccc6cc4[Si]5(c4ccccc4)c4ccccc4)cc3)c3cc4ccccc4c4ccccc34)cc2)cc1]

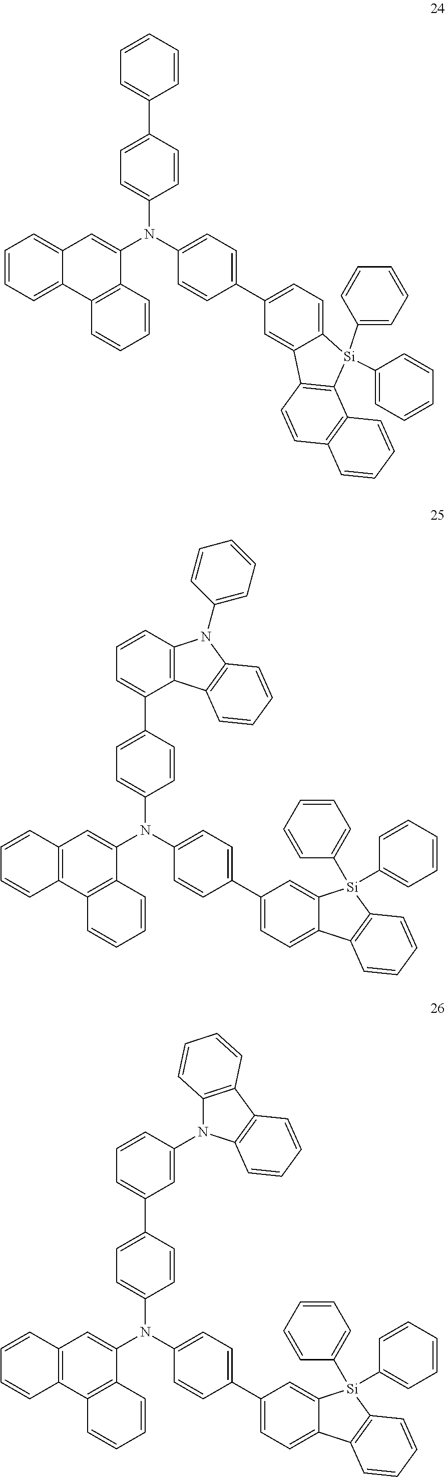 [SMILES: c1ccc(-c2ccc(N(c3ccc(-c4ccc5c(c4)-c4ccc6ccccc6c4[Si]5(c4ccccc4)c4ccccc4)cc3)c3cc4ccccc4c4ccccc34)cc2)cc1 ; c1ccc(-n2c3ccccc3c3c(-c4ccc(N(c5ccc(-c6ccc7c(c6)[Si](c6ccccc6)(c6ccccc6)c6ccccc6-7)cc5)c5cc6ccccc6c6ccccc56)cc4)cccc32)cc1 ; c1ccc([Si]2(c3ccccc3)c3ccccc3-c3ccc(-c4ccc(N(c5ccc(-c6cccc(-n7c8ccccc8c8ccccc87)c6)cc5)c5cc6ccccc6c6ccccc56)cc4)cc32)cc1]

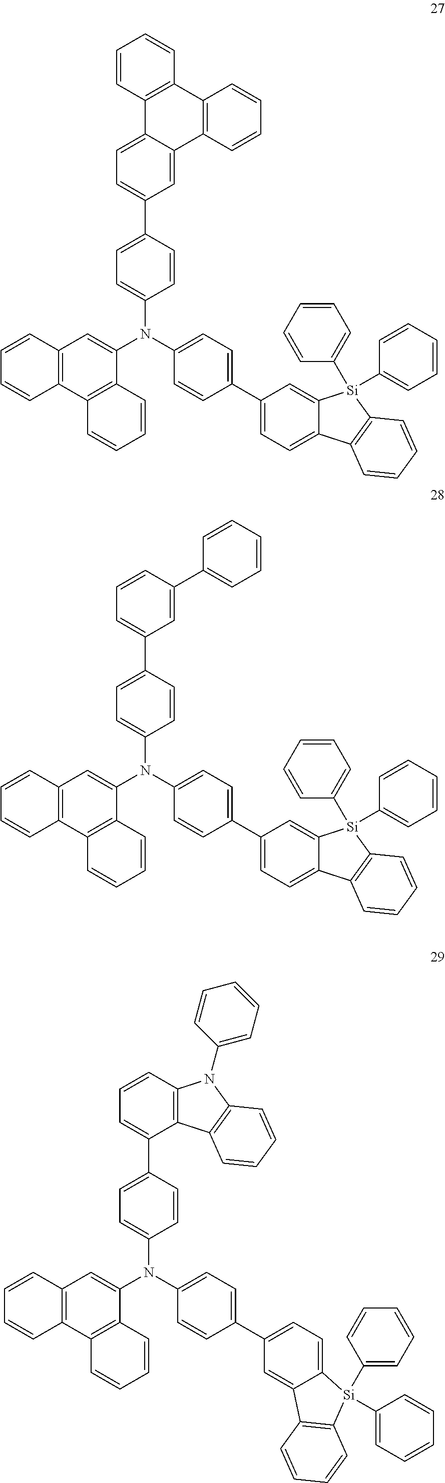 [SMILES: c1ccc([Si]2(c3ccccc3)c3ccccc3-c3ccc(-c4ccc(N(c5ccc(-c6ccc7c8ccccc8c8ccccc8c7c6)cc5)c5cc6ccccc6c6ccccc56)cc4)cc32)cc1 ; c1ccc(-c2cccc(-c3ccc(N(c4ccc(-c5ccc6c(c5)[Si](c5ccccc5)(c5ccccc5)c5ccccc5-6)cc4)c4cc5ccccc5c5ccccc45)cc3)c2)cc1 ; c1ccc(-n2c3ccccc3c3c(-c4ccc(N(c5ccc(-c6ccc7c(c6)-c6ccccc6[Si]7(c6ccccc6)c6ccccc6)cc5)c5cc6ccccc6c6ccccc56)cc4)cccc32)cc1]

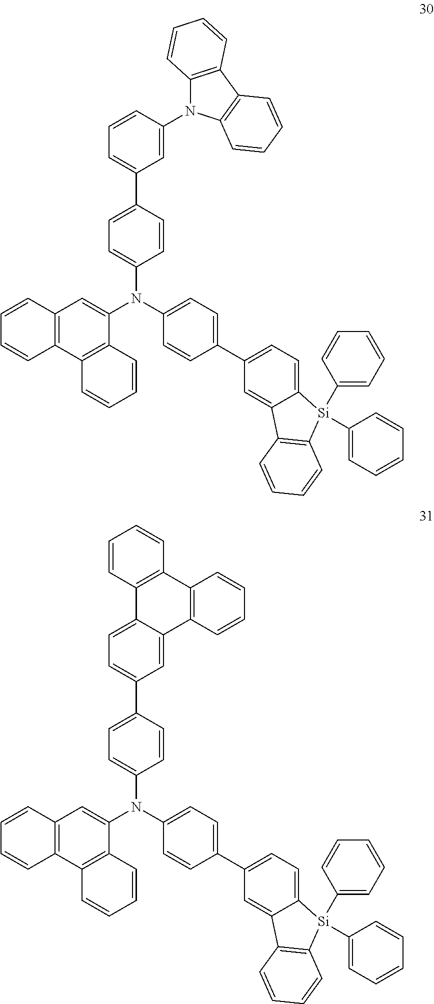 [SMILES: c1ccc([Si]2(c3ccccc3)c3ccccc3-c3cc(-c4ccc(N(c5ccc(-c6cccc(-n7c8ccccc8c8ccccc87)c6)cc5)c5cc6ccccc6c6ccccc56)cc4)ccc32)cc1 ; c1ccc([Si]2(c3ccccc3)c3ccccc3-c3cc(-c4ccc(N(c5ccc(-c6ccc7c8ccccc8c8ccccc8c7c6)cc5)c5cc6ccccc6c6ccccc56)cc4)ccc32)cc1]

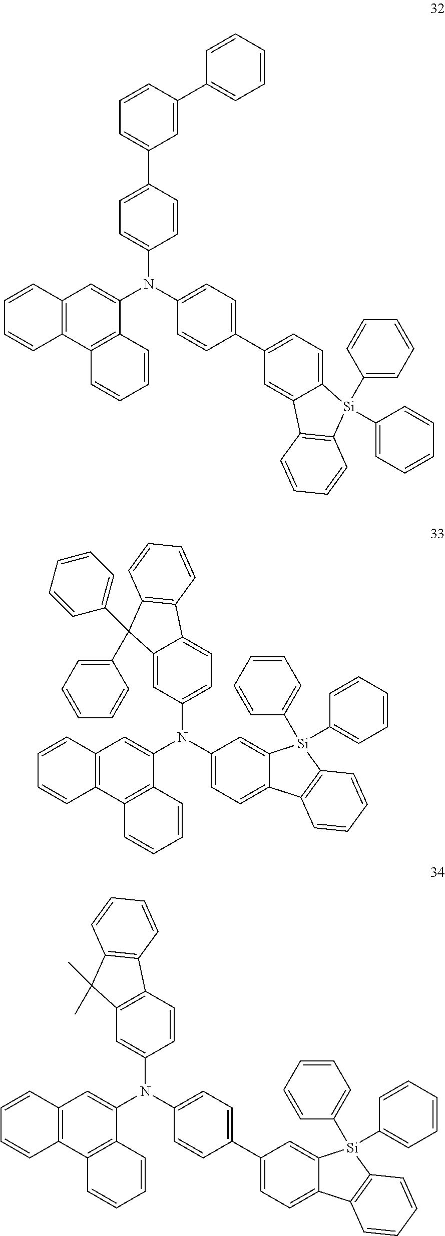 [SMILES: c1ccc(-c2cccc(-c3ccc(N(c4ccc(-c5ccc6c(c5)-c5ccccc5[Si]6(c5ccccc5)c5ccccc5)cc4)c4cc5ccccc5c5ccccc45)cc3)c2)cc1 ; c1ccc(C2(c3ccccc3)c3ccccc3-c3ccc(N(c4ccc5c(c4)[Si](c4ccccc4)(c4ccccc4)c4ccccc4-5)c4cc5ccccc5c5ccccc45)cc32)cc1 ; CC1(C)c2ccccc2-c2ccc(N(c3ccc(-c4ccc5c(c4)[Si](c4ccccc4)(c4ccccc4)c4ccccc4-5)cc3)c3cc4ccccc4c4ccccc34)cc21]

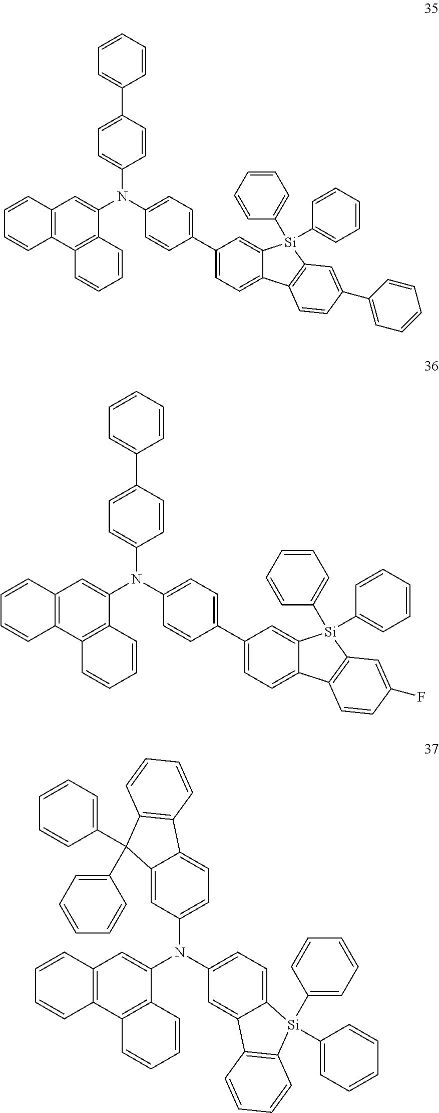 [SMILES: c1ccc(-c2ccc(N(c3ccc(-c4ccc5c(c4)[Si](c4ccccc4)(c4ccccc4)c4cc(-c6ccccc6)ccc4-5)cc3)c3cc4ccccc4c4ccccc34)cc2)cc1 ; Fc1ccc2c(c1)[Si](c1ccccc1)(c1ccccc1)c1cc(-c3ccc(N(c4ccc(-c5ccccc5)cc4)c4cc5ccccc5c5ccccc45)cc3)ccc1-2 ; c1ccc(C2(c3ccccc3)c3ccccc3-c3ccc(N(c4ccc5c(c4)-c4ccccc4[Si]5(c4ccccc4)c4ccccc4)c4cc5ccccc5c5ccccc45)cc32)cc1]

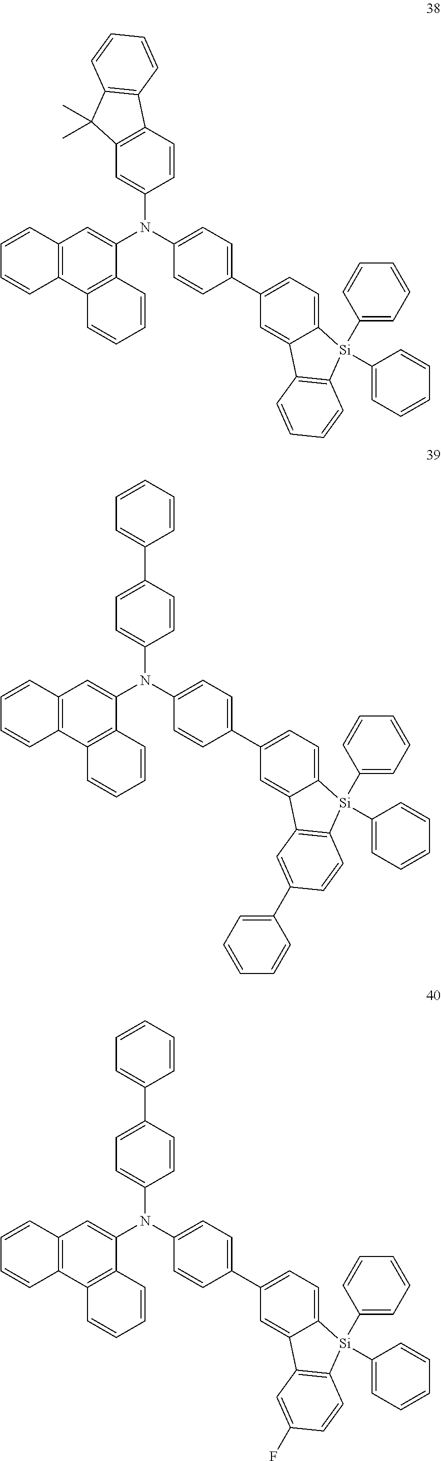 [SMILES: CC1(C)c2ccccc2-c2ccc(N(c3ccc(-c4ccc5c(c4)-c4ccccc4[Si]5(c4ccccc4)c4ccccc4)cc3)c3cc4ccccc4c4ccccc34)cc21 ; c1ccc(-c2ccc(N(c3ccc(-c4ccc5c(c4)-c4cc(-c6ccccc6)ccc4[Si]5(c4ccccc4)c4ccccc4)cc3)c3cc4ccccc4c4ccccc34)cc2)cc1 ; Fc1ccc2c(c1)-c1cc(-c3ccc(N(c4ccc(-c5ccccc5)cc4)c4cc5ccccc5c5ccccc45)cc3)ccc1[Si]2(c1ccccc1)c1ccccc1]

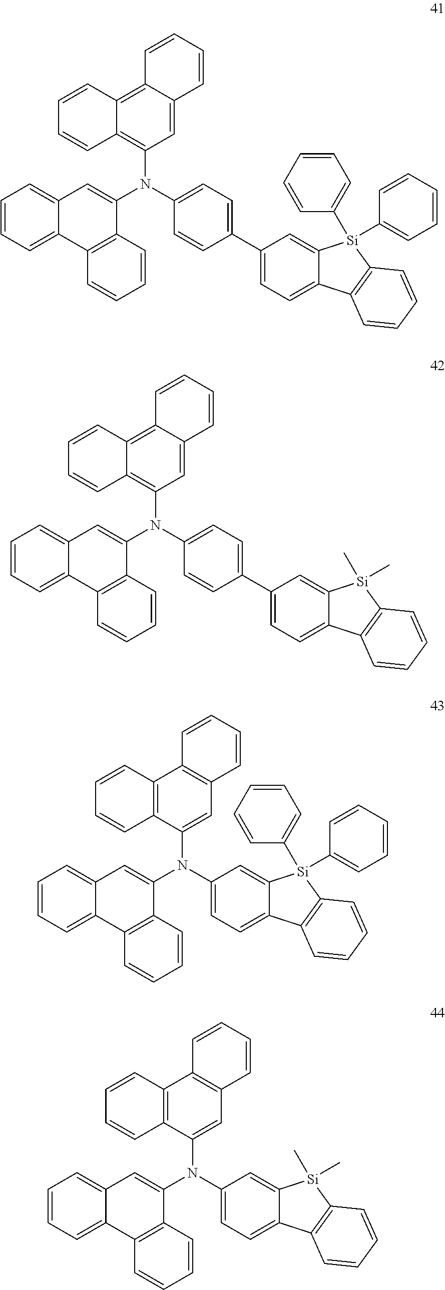 [SMILES: c1ccc([Si]2(c3ccccc3)c3ccccc3-c3ccc(-c4ccc(N(c5cc6ccccc6c6ccccc56)c5cc6ccccc6c6ccccc56)cc4)cc32)cc1 ; C[Si]1(C)c2ccccc2-c2ccc(-c3ccc(N(c4cc5ccccc5c5ccccc45)c4cc5ccccc5c5ccccc45)cc3)cc21 ; c1ccc([Si]2(c3ccccc3)c3ccccc3-c3ccc(N(c4cc5ccccc5c5ccccc45)c4cc5ccccc5c5ccccc45)cc32)cc1 ; C[Si]1(C)c2ccccc2-c2ccc(N(c3cc4ccccc4c4ccccc34)c3cc4ccccc4c4ccccc34)cc21]

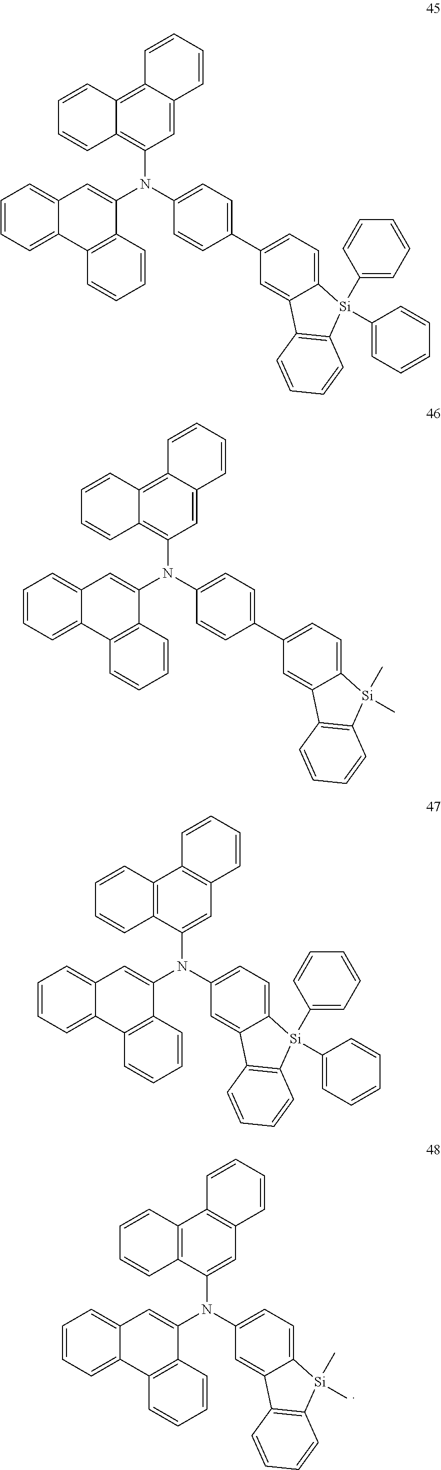

### 2. Configuration of Organic EL Device Including Material for an Organic EL Device

Referring to the drawing, an organic EL device using the material for an organic EL device according to embodiments of the present disclosure will be described hereinafter. The drawing is a schematic cross-sectional view of an organic EL device according to an embodiment of the present disclosure.

As shown in the drawing, an organic EL device 100 according to an embodiment of the present disclosure may include a substrate 110, a first electrode 120 positioned on the substrate 110, a hole injection layer 130 positioned on the first electrode 120, a hole transport layer 140 positioned on the hole injection layer 130, an emission layer 150 positioned on the hole transport layer 140, an electron transport layer 160 positioned on the emission layer 150, an electron injection layer 170 positioned on the electron transport layer 160 and a second electrode 180 positioned on the electron injection layer 170.

Here, the material for an organic EL device according to embodiments of the present disclosure may be included in at least one of the hole transport layer and the emission layer. For example, the material for an organic EL device may be included in both (e.g., each) of the hole transport and emission layers. In some embodiments, the material for an organic EL device may be included in the hole transport layer 140.

Each of the organic thin layers positioned between the first electrode 120 and the second electrode 180 of the organic EL device may be formed by one or more suitable methods such as, for example, an evaporation method.

The substrate 110 may be any suitable substrate capable of being used in an organic EL device. For example, the substrate 110 may be a glass substrate, a semiconductor substrate, or a transparent plastic substrate.

The first electrode 120 may be, for example, an anode and may be formed by an evaporation method, a sputtering method, etc. on the substrate 110. For example, the first electrode 120 may be formed as a transmission type electrode (e.g., transmission electrode) using, without limitation, a metal, an alloy, a conductive compound, etc. having high work function. The first electrode 120 may be formed using, for example, transparent and highly conductive indium tin oxide (In₂O₃—SnO₂, “ITO”), indium zinc oxide (In₂O₃—ZnO, “IZO”), tin oxide (SnO₂), zinc oxide (ZnO), etc. In addition, the first electrode 120 may be formed as a reflection type electrode (e.g., reflection electrode) using, without limitation, magnesium (Mg), aluminum (Al), etc.

On the first electrode 120, the hole injection layer 130 may be formed. The hole injection layer 130 is a layer having the function of facilitating the injection of holes from the first electrode 120 and may be formed, for example, on the first electrode 120 to a thickness from about 10 nm to about 150 nm. The hole injection layer 130 may be formed using any suitable material. Non-limiting examples of the material for forming the hole injection layer may include, for example, triphenylamine-containing polyether ketone (TPAPEK), 4-isopropyl-4′-methyldiphenyliodoniumtetrakis(pentaflorophenyl)borate (PPBI), N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methyl phenylamino)triphenylamine (m-MTDATA), N,N′-di(1-naphthyl)-N,N′-diphenylbenzidine (NPB), 4,4′,4″-tris{N,N-diamino}triphenylamine (TDATA), 4,4′,4″-tris(N,N-2-naphthylphenylamino)triphenylamine (2-TNATA), polyaniline/dodecylbenzenesulfonic acid (Pani/DBSA), poly(3,4-ethylenedioxythiophene)/poly(4-styrenesulfonate) (PEDOT/PSS), polyaniline/camphorsulfonic acid (Pani/CSA), polyaniline/poly(4-styrenesulfonate (PANI/PSS), etc.

On the hole injection layer 130, the hole transport layer 140 may be formed. The hole transport layer 140 may be formed by stacking a plurality of layers. The hole transport layer 140 is a layer including a hole transport material and having a hole transporting function and the hole transport layer 140 may be formed, for example, on the hole injection layer 130 to a thickness from about 10 nm to about 150 nm. For example, the hole transport layer 140 may be formed using the material for an organic EL device according to embodiments of the present disclosure. In the embodiments where the material for an organic EL device is used as the host material of the emission layer 150, the hole transport layer 140 may be formed using any suitable hole transport material. Non-limiting examples of the hole transport material include, for example, 1,1-bis[(di-4-tolylamino)phenyl]cyclohexane (TAPC), a carbazole derivative such as N-phenyl carbazole and polyvinyl carbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(1-naphthyl)-N,N′-diphenylbenzidine (NPB), etc.

On the hole transport layer 140, the emission layer 150 may be formed. The emission layer 150 may be a layer emitting light via fluorescence, phosphorescence, etc., and the emission layer may be formed to a thickness from about 10 nm to about 60 nm. The material for the emission layer 150 may be any suitable luminescent material, without specific limitation, and in some embodiments, may be selected from a fluoranthene derivative, a pyrene derivative, an arylacetylene derivative, a fluorene derivative, a perylene derivative, a chrysene derivative, etc. For example, the luminescent material may be selected from the pyrene derivative, the perylene derivative and the anthracene derivative. In some embodiments, as the material for the emission layer 150, an anthracene derivative represented by the following Formula 5 may be used.

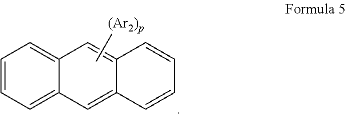

In the above Formula 5, Ar₂ is selected from hydrogen, deuterium, a substituted or unsubstituted alkyl group having 1 to 50 carbon atoms, a substituted or unsubstituted cycloalkyl group having 3 to 50 carbon atoms for forming a ring, a substituted or unsubstituted alkoxy group having 1 to 50 carbon atoms, a substituted or unsubstituted aralkyl group having 7 to 50 carbon atoms, a substituted or unsubstituted aryloxy group having 6 to 50, carbon atoms for forming a ring, a substituted or unsubstituted arylthio group having 6 to 50 carbon atoms for forming a ring, a substituted or unsubstituted alkoxycarbonyl group having 2 to 50 carbon atoms, a substituted or unsubstituted aryl group having 6 to 50 carbon atoms for forming a ring, a substituted or unsubstituted heteroaryl group having 5 to 50 carbon atoms for forming a ring, a substituted or unsubstituted silyl group, a carboxyl group, a halogen atom, a cyano group, a nitro group and a hydroxyl group; and p is an integer selected from 1 to 10.

For example, in Formula 5, Ar₂ may include a phenyl group, a biphenyl group, a terphenyl group, a naphthyl group, an anthryl group, a phenanthryl group, a fluorenyl group, an indenyl group, a pyrenyl group, an acetonaphthenyl group, a fluoranthenyl group, a triphenylenyl group, a pyridyl group, a furanyl group, a pyranyl group, a thienyl group, a quinolyl group, an isoquinolyl group, a benzofuranyl group, a benzothienyl group, an indolyl group, a carbazolyl group, a benzoxazolyl group, a benzothiazolyl group, a quinoxalyl group, a pyrazolyl group, a dibenzofuranyl group, a dibenzothienyl group, etc. In some embodiments, the phenyl group, the biphenyl group, the terphenyl group, the fluorenyl group, the carbazolyl group, the dibenzofuranyl group, etc. may be used as Ar₂.

A compound represented by Formula 5 may be represented by any of the following Compounds a-1 to a-12, but is not limited thereto. In the following formulae, “D” may refer to deuterium.

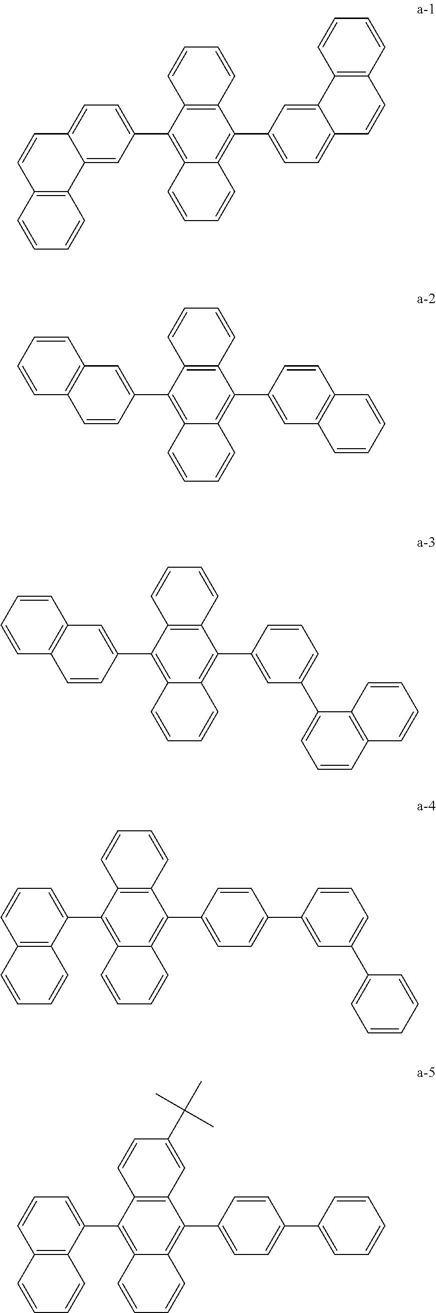

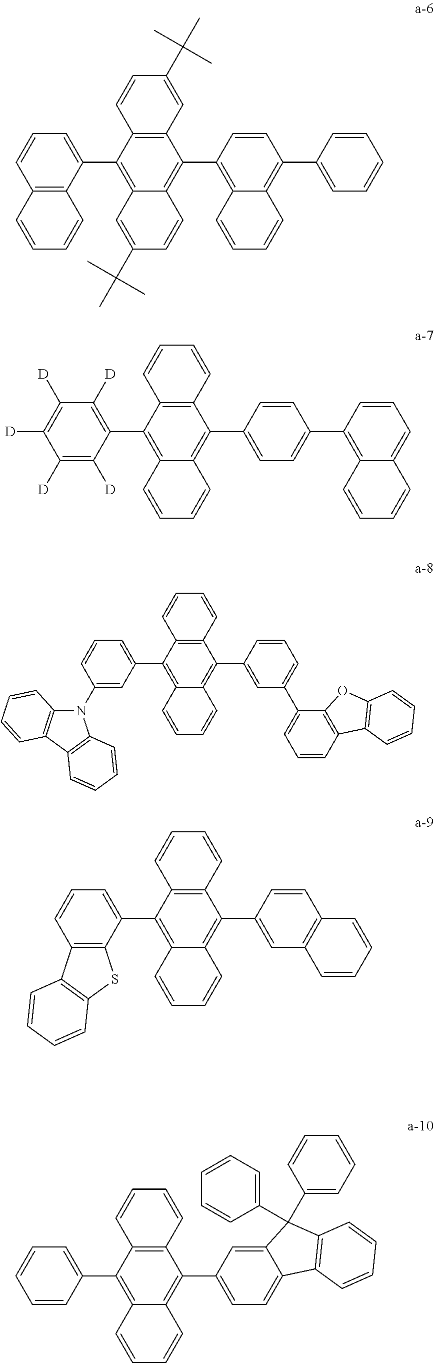

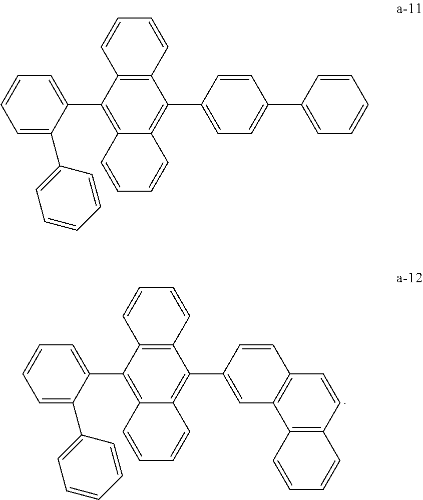

The emission layer 150 may include a dopant such as, for example, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalene-2-yl)vinyl)phenyl)-N-phenylbenzeneamine (N-BDAVBi)), perylene and/or the derivative thereof (e.g., 2,5,8,11-tetra-t-butylperylene (TBPe)), pyrene and/or the derivative thereof (e.g., 1.1-dipyrene, 1,4-dipyrenylbenzene and 1,4-bis(N,N-diphenylamino)pyrene), but embodiments of the present disclosure are not limited thereto.

On the emission layer 150, an electron transport layer 160 including, for example, tris(8-hydroxyquinolinato)aluminum (Alq3) and/or a material having a nitrogen-containing aromatic ring (e.g., a material including a pyridine ring such as 1,3,5-tri[(3-pyridyl)-phen-3-yl]benzene, a material including a triazine ring such as 2,4,6-tris(3′-(pyridin-3-yl)biphenyl-3-yl)-1,3,5-triazine, a material including an imidazole derivative such as 2-(4-(N-phenylbenzoimidazolyl-1-ylphenyl)-9,10-dinaphthylanthracene)) may be formed. The electron transport layer 160 is a layer including an electron transport material and having an electron transporting function and the electron transport layer 160 may be formed on the emission layer 150 to a thickness from about 15 nm to about 50 nm. On the electron transport layer 160, the electron injection layer 170 may be formed using a material including, for example, lithium fluoride, lithium-8-quinolinato (Liq), etc. The electron injection layer 170 is a layer having function of facilitating the injection of electrons from the second electrode 180 and the electron injection layer 170 may be formed to a thickness from about 0.3 nm to about 9 nm.

In some embodiments, on the electron injection layer 170, the second electrode 180 may be formed. The second electrode 180 may be, for example, a cathode. In some embodiments, the second electrode 180 may be formed as a reflection type electrode (e.g., reflection electrode) using, without limitation, a metal, an alloy, a conductive compound, etc. having low work function. The second electrode 180 may be formed using, for example, lithium (Li), magnesium (Mg), aluminum (Al), aluminum-lithium (Al—Li), calcium (Ca), magnesium-indium (Mg—In), magnesium-silver (Mg—Ag), etc. In some embodiments, the second electrode 180 may be formed as a transmission type electrode (e.g., transmission electrode) using, without limitation, ITO, IZO, etc. Each of the above-mentioned layers may be formed by selecting one or more of appropriate layer forming methods such as, for example, a vacuum evaporation method, a sputtering method and/or other suitable coating methods, depending on the materials used for forming each layer.

As described above, a structure of the organic EL device 100 according to an embodiment of the present disclosure has been explained. The organic EL device 100 including the material for an organic EL device according to embodiments of the present disclosure may have a decreased driving voltage and improved emission efficiency.

However, the structure of the organic EL device 100 according to embodiments of the present disclosure is not limited to the above-described embodiments; and the organic EL device 100 may be formed using the structures of various other suitable organic EL devices. For example, the organic EL device 100 may be provided without one or more layers selected from the hole injection layer 130, the electron transport layer 160 and the electron injection layer 170. In some embodiments, the layers included in the organic EL device 100 may be each independently formed as a single layer or as a plurality of layers.

In some embodiments, the organic EL device 100 may include a hole blocking layer between the electron transport layer 160 and the emission layer 150 to prevent or reduce the diffusion of triplet excitons or holes into the electron transport layer 160. The hole blocking layer may be formed using, for example, an oxadiazole derivative, a triazole derivative, and/or a phenanthroline derivative.

### EXAMPLES

Hereinafter, the organic EL device according to one or more embodiments of the present disclosure will be explained in more detail by referring to examples and comparative examples. However, the following examples are only for illustration of the organic EL device according to embodiments of the present disclosure, and the organic EL device according to embodiments of the present disclosure is not limited thereto.

### Synthetic Example 1

### Synthesis of Compound 3

Compound 3 was synthesized by the following synthetic mechanism”

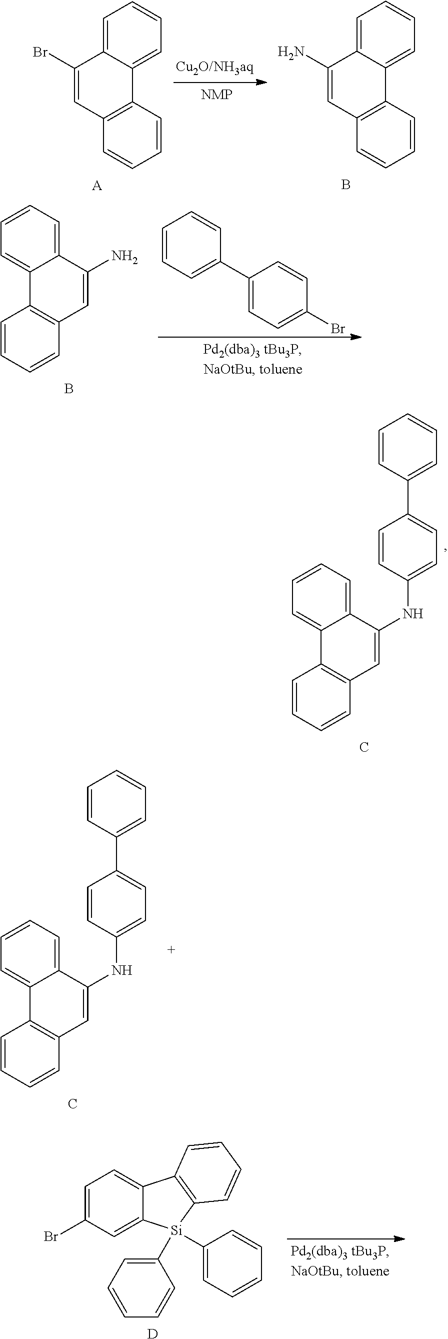

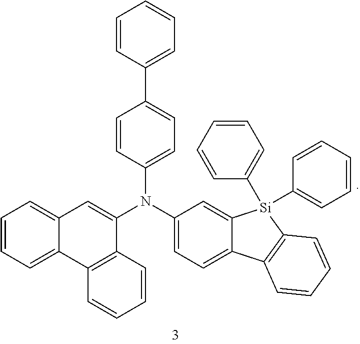 [SMILES: c1ccc(-c2ccc(N(c3ccc4c(c3)[Si](c3ccccc3)(c3ccccc3)c3ccccc3-4)c3cc4ccccc4c4ccccc34)cc2)cc1]

### Synthesis of Compound B

Under an argon atmosphere, 15.00 g of Compound A, 0.85 g of cuprous oxide, 20 ml of an aqueous ammonia solution and 70 ml of NMP were added to a 500 ml, three necked flask, followed by heating the mixture at about 110° C. for about 25 hours. After air cooling the resultant, water was added thereto, an organic layer was separated therefrom, and solvents were distilled. The crude product thus obtained was separated using silica gel column chromatography (using a mixture solvent of hexane and ethyl acetate) to produce 7.4 g of Compound B as a white solid (Yield 66%). The molecular weight of Compound B thus obtained was measured using Fast Atom Bombardment Mass Spectrometry (FAB-MS), and a value of 193 (C₁₄H₁₁N) was obtained.

### Synthesis of Compound C

Under an argon atmosphere, 1.00 g of Compound B, 1.21 g of 4-bromobiphenyl, 0.27 g of tris(dibenzylideneacetone)palladium(0), 0.088 g of tri-tert-butylphosphine and 3.98 g of sodium tert-butoxide were added to a 300 ml, three necked flask, followed by heating and refluxing the mixture in 200 ml of a toluene solvent for about 7 hours. After air cooling the resulting reactant, water was added thereto, an organic layer was separated therefrom, and solvents were distilled. The crude product thus obtained was separated using silica gel column chromatography (using a mixture solvent of toluene and hexane) to produce 1.89 g of Compound C as a white solid (Yield 50%).

### Synthesis of Compound 3

Under an argon atmosphere, 1.00 g of Compound C, 1.03 g of Compound D, 0.07 g of tris(dibenzylideneacetone)dipalladium(0), 0.10 g of tri-tert-butylphosphine and 1.99 g of sodium tert-butoxide were added to a 300 nil, three necked flask, followed by heating and refluxing the mixture in 300 ml of a toluene solvent for about 7 hours. After air cooling the resulting reactant, water was added thereto, an organic layer was separated therefrom, and solvents were distilled. The crude product thus obtained was separated using silica gel column chromatography (using a mixture solvent of toluene and hexane) to produce 1.52 g of Compound 3 as a white solid (Yield 65%). The molecular weight of Compound 3 thus obtained was measured using FAB-MS, and a value of 677 (C₅₀H₃₅NSi) was obtained.

### Synthetic Example 2

### Synthesis of Compound 5

Compound 5 was synthesized by the following synthetic mechanism:

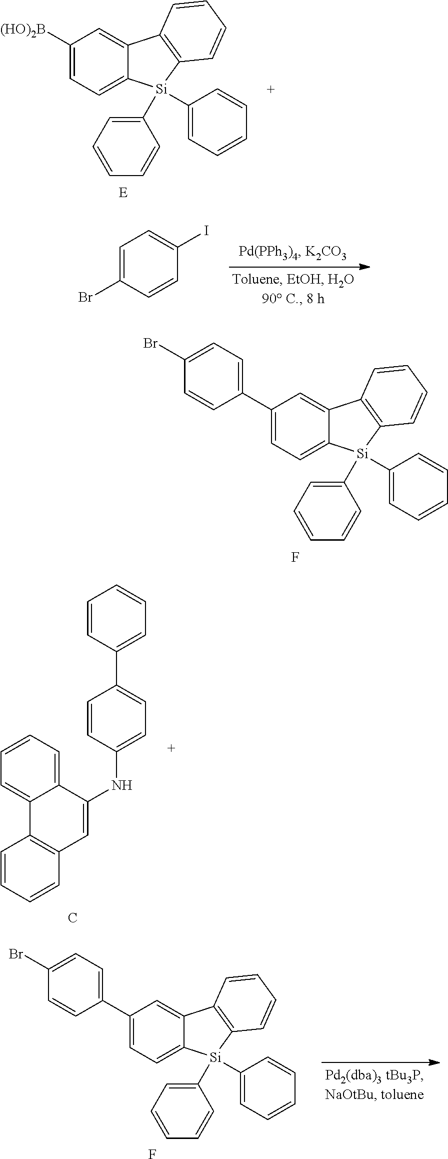

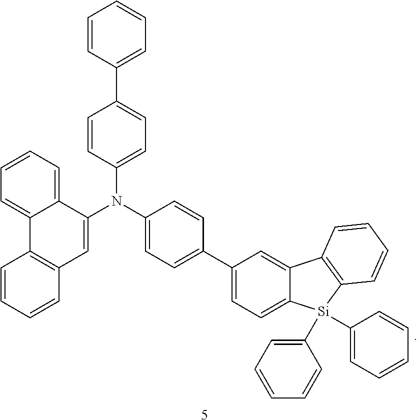 [SMILES: c1ccc(-c2ccc(N(c3ccc(-c4ccc5c(c4)-c4ccccc4[Si]5(c4ccccc4)c4ccccc4)cc3)c3cc4ccccc4c4ccccc34)cc2)cc1 ; "5"]

### Synthesis of Compound F

Under an argon atmosphere, 1.00 g of Compound E, 7.50 g of 1-bromo-4-iodobenzene, 3.97 g of tetrakistriphenylphosphinepalladium (Pd(PPh₃)₄), and 11.1 g of potassium carbonate were added to a 500 ml, three necked flask, followed by heating and stirring the resultant in a mixture solvent of 133 mL of toluene and 66 of water at about 90° C. for about 8 hours. After air cooling the resulting reactant, water was added thereto, an organic layer was separated therefrom, and solvents were distilled. The crude product thus obtained was separated using silica gel column chromatography (using a mixture solvent of toluene and hexane) and recrystallized (using a mixture solvent of toluene and ethanol) to produce 11.5 g of Compound F as a white solid (Yield 89%). The molecular weight of Compound F thus obtained was measured using FAB-MS, and a value of 488 (C₃₀H₂₁BrSi) was obtained.

### Synthesis of Compound 5

Compound 5 was synthesized using the same (or substantially the same) synthetic method and separation method as those used for synthesizing Compound 3 except that Compound F instead of Compound D was used to produce Compound 5 as a white solid in 65% yield. The molecular weight of Compound 5 thus obtained was measured using FAB-MS, and a value of 753 (C₅₆H₃₉NSi) was obtained.

### Synthetic Example 3

### Synthesis of Compound 7

Compound 7 was synthesized by the following synthetic mechanism:

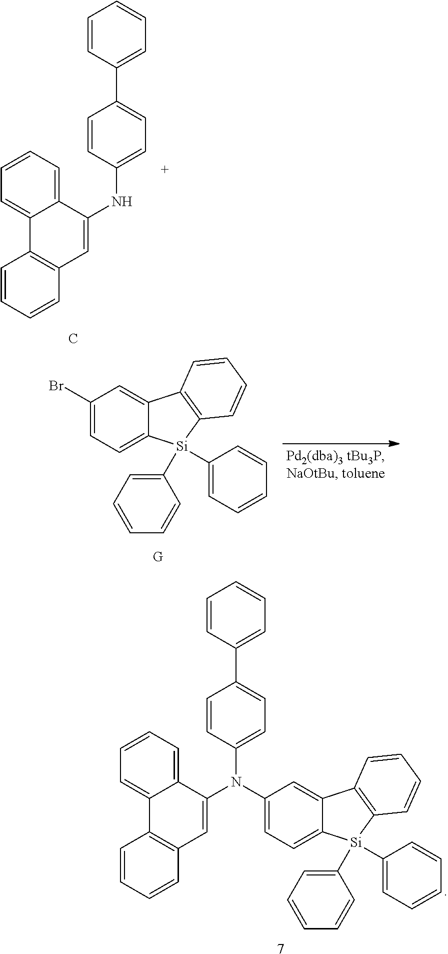

Under an argon atmosphere, 1.00 g of Compound C, 1.03 g of Compound G, 0.07 g of tris(dibenzylideneacetone)palladium(0), 0.10 g of tri-tert-butylphosphine and 1.99 g of sodium tert-butoxide were added to a 300 ml, three necked flask, followed by heating and refluxing the mixture in 300 ml of a toluene solvent for about 7 hours. After air cooling the resulting reactant, water was added thereto, an organic layer was separated therefrom, and solvents were distilled. The crude product thus obtained was separated using silica gel column chromatography (using a mixture solvent of toluene and hexane) to produce 1.04 g of Compound 7 as a white solid (Yield 60%). The molecular weight of Compound 7 thus obtained was measured using FAB-MS, and a value of 677 (C₅₀H₃₅NSi) was obtained.

### Synthetic Example 4

### Synthesis of Compound 8

Compound 8 was synthesized by the following synthetic mechanism:

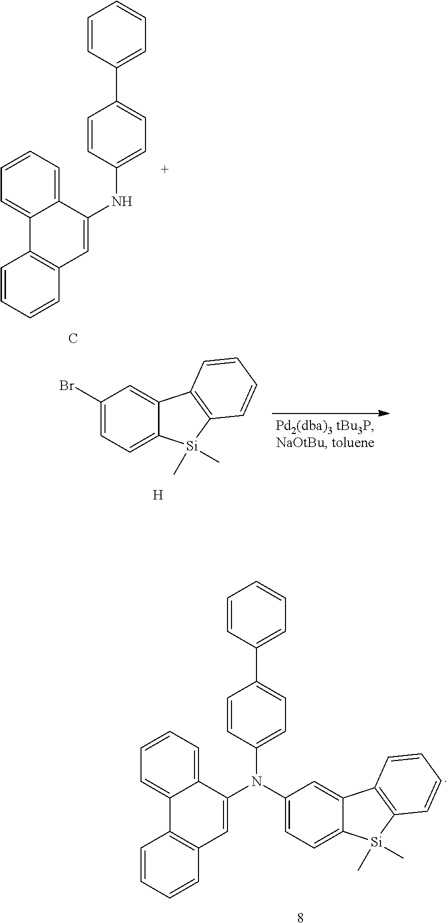

Compound 8 was synthesized using the same (or substantially the same) synthetic method and separation method as those used for synthesizing Compound 7 except that Compound H instead of Compound G was used to produce Compound 8 as a white solid in 72% yield. The molecular weight of Compound 8 thus obtained was measured using FAB-MS, and a value of 553 (C₄₀H₃₁NSi) was obtained.

### Synthetic Example 5

### Synthesis of Compound 14

Compound 14 was synthesized by the following synthetic mechanism:

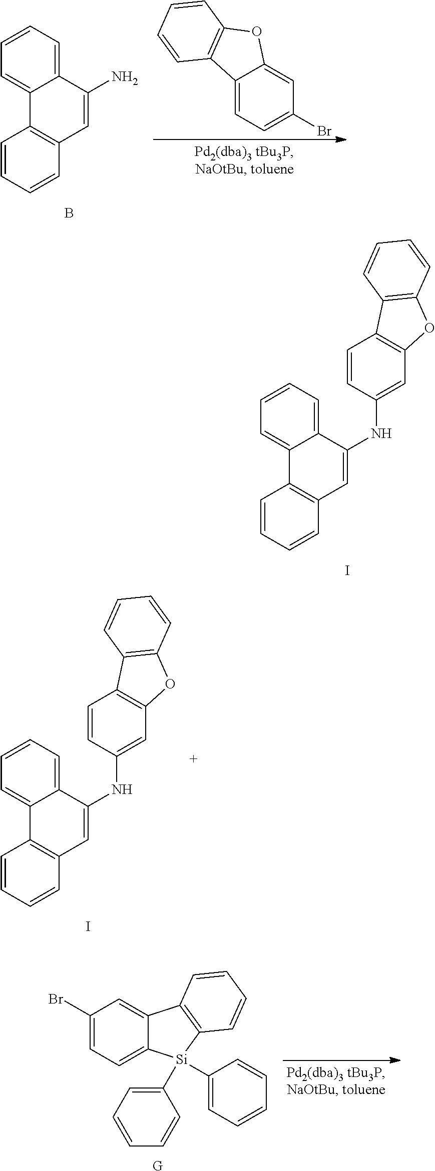

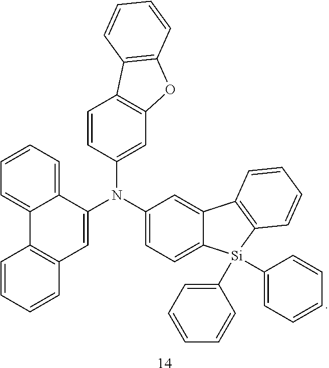

### Synthesis of Compound I

Compound I was synthesized using the same (or substantially the same) synthetic method and separation method as those used for synthesizing Compound C except that 3-bromodibenzofuran instead of 4-bromobiphenyl was used to produce Compound I as a white solid in 86% yield. The molecular weight of Compound I thus obtained was measured using FAB-MS, and a value of 359 (C₂₆H₁₇NO) was obtained.

### Synthesis of Compound 14

Compound 14 was synthesized using the same (or substantially the same) synthetic method and separation method as those used for synthesizing Compound 7 except that Compound I instead of Compound C was used to produce Compound 14 as a white solid in 80% yield. The molecular weight of Compound 14 thus obtained was measured using FAB-MS, and a value of 691 (C₅₀H₃₃NOSi) was obtained.

### Synthetic Example 6

### Synthesis of Compound 21

Compound 21 was synthesized by the following synthetic mechanism:

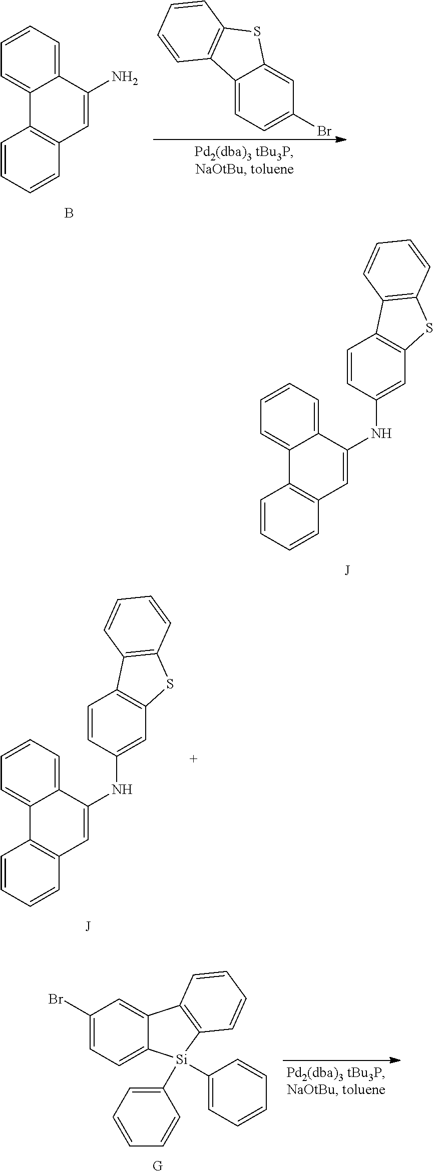

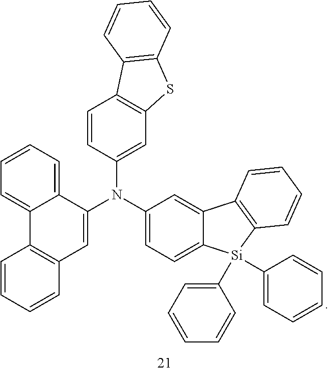

### Synthesis of Compound J

Compound J was synthesized using the same (or substantially the same) synthetic method and separation method as those used for synthesizing Compound C except that 3-bromodibenzothiophene instead of 4-bromobiphenyl was used to produce Compound J as a white solid in 84% yield. The molecular weight of Compound J thus obtained was measured using FAB-MS, and a value of 375 (C₂₆H₁₇NS) was obtained.

### Synthesis of Compound 21

Compound 21 was synthesized using the same (or substantially the same) synthetic method and separation method as those used for synthesizing Compound 7 except that Compound J instead of Compound C was used to produce Compound 21 as a white solid in 76% yield. The molecular weight of Compound 21 thus obtained was measured using FAB-MS, and a value of 707 (C₅₀H₃₃NSSi) was obtained.

### Synthetic Example 7

### Synthesis of Compound 47

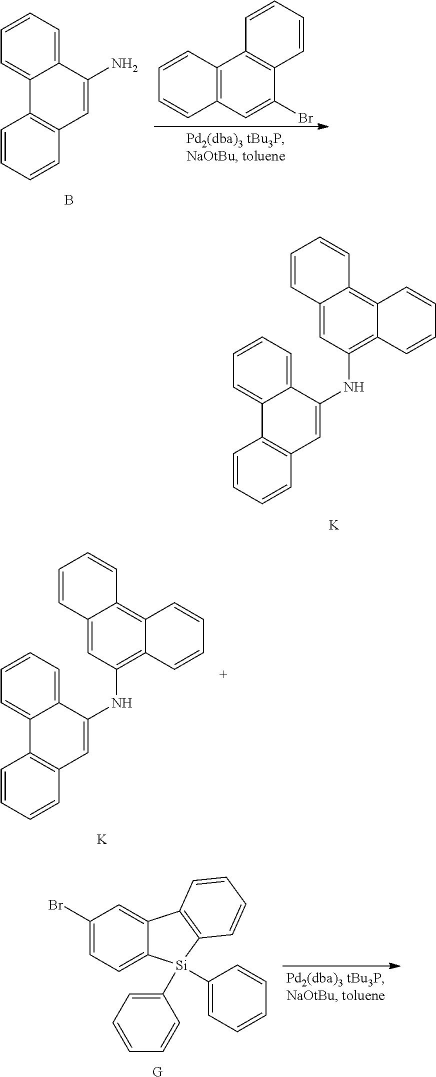

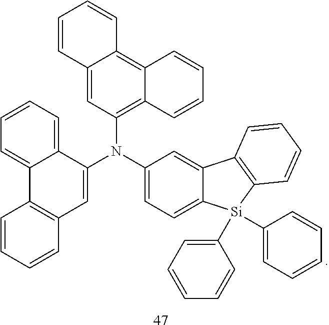

### Synthesis of Compound K

Compound K was synthesized using the same (or substantially the same) synthetic method and separation method as those used for synthesizing Compound C except that 9-bromophenanthrene instead of 4-bromobiphenyl was used to produce Compound K as a white solid in 69% yield. The molecular weight of Compound K thus obtained was measured using FAB-MS, and a value of 369 (C₂₈H₁₉N) was obtained.

### Synthesis of Compound 47

Compound 47 was synthesized using the same (or substantially the same) synthetic method and separation method as those used for synthesizing Compound 7 except that Compound K instead of Compound C was used to produce Compound 47 as a white solid in 69% yield. The molecular weight of Compound 47 thus obtained was measured using FAB-MS, and a value of 701 (C₅₂H₃₅NSi) was obtained.

### Manufacturing of Organic EL Device

An organic EL device was manufactured by the following method. First, on an ITO-glass substrate patterned and washed in advance, surface treatment using UV-ozone (O₃) was conducted. The layer thickness of the resulting ITO layer (used as the first electrode) was about 150 nm. After ozone treatment, the substrate was washed. After finishing washing, the substrate was set in a glass bell jar type evaporator (e.g., glass bell jar evaporator) for forming an organic layer, and a hole injection layer, a HTL (a hole transport layer), an emission layer and an electron transport layer were sequentially evaporated one by one in a vacuum degree of about 10⁻⁴ to about 10⁻⁵ Pa. The material for the hole injection layer was 2-TNATA, and the thickness of the hole injection layer was about 60 nm. The materials for the respective HTLs are shown in Table 1, and the thickness thereof was about 30 nm.

The thickness of the emission layer was about 25 nm. The host for the emission material was 9,10-di(2-naphthyl)anthracene (ADN). The dopant was 2,5,8,11-tetra-t-butylperylene (TBP). The doping amount of the dopant was about 3 wt % on the basis of the amount of the host. The material for the electron transport layer was Alq3, and the thickness of the electron transport layer was about 25 nm. Subsequently, the substrate was transferred to a glass bell jar type evaporator (e.g., glass bell jar evaporator) for forming a metal layer, and the electron injection layer and a cathode material were sequentially evaporated in a vacuum degree of about 10⁻⁴ to about 10⁻⁵ Pa. The material for the electron injection layer was LiF, and the thickness of the electron injection layer was about 1.0 nm. The material for the second electrode was Al, and the thickness thereof was about 100 nm.

TABLE 1

| Example of device | | | Emission |
|---|---|---|---|
| manufacture | HTL | Voltage (V) | efficiency (cd/A) |
| Example 1 | Compound 3 | 6.3 | 7.3 |
| Example 2 | Compound 5 | 6.1 | 7.6 |
| Example 3 | Compound 7 | 6.3 | 7.8 |
| Example 4 | Compound 8 | 6.5 | 7.4 |
| Example 5 | Compound 14 | 6.1 | 7.6 |
| Example 6 | Compound 21 | 6.1 | 7.5 |
| Example 7 | Compound 47 | 6.4 | 7.3 |
| Comparative | Comparative | 7.5 | 6.0 |
| Example 1 | Compound C1 | | |
| Comparative | Comparative | 7.2 | 6.5 |
| Example 2 | Compound C2 | | |
| Comparative | Comparative | 7.3 | 5.1 |
| Example 3 | Compound C3 | | |

In Table 1, Comparative Compounds C1, C2, and C3 respectively used in Comparative Examples 1, 2, and 3 are illustrated below. Comparative Compound C1 has a diamine structure and does not include a phenanthrene group when compared to the monoamine derivative of Formula 1 according to embodiments of the present disclosure. Comparative Compound C2 includes a biphenyl group instead of the phenanthrene group and has a structure in which a covalent bond forming a dibenzosilole ring (as in the monoamine derivative of Formula 1) is cleaved. Comparative Compound C3 includes a phenanthrene group similar to the monoamine derivative of Formula 1 according to embodiments of the present disclosure, however Comparative Compound C3 is different from the monoamine derivative of Formula 1 according to embodiments of the present disclosure in that it includes a pyrenyl group instead of a dibenzosilolyl group.

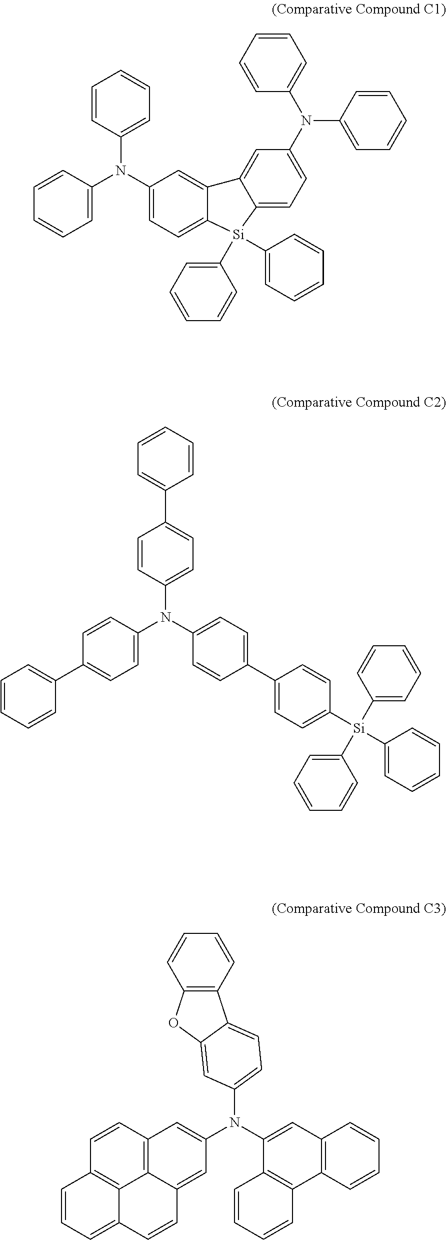 [SMILES: c1ccc(N(c2ccccc2)c2ccc3c(c2)-c2cc(N(c4ccccc4)c4ccccc4)ccc2[Si]3(c2ccccc2)c2ccccc2)cc1 ; c1ccc(-c2ccc(N(c3ccc(-c4ccccc4)cc3)c3ccc(-c4ccc([Si](c5ccccc5)(c5ccccc5)c5ccccc5)cc4)cc3)cc2)cc1 ; c1ccc2c(c1)cc(N(c1cc3ccc4cccc5ccc(c1)c3c45)c1ccc3c(c1)oc1ccccc13)c1ccccc12]

### Evaluation of Properties

The driving voltage and the emission life of each of the organic EL devices manufactured according to the above-described examples and comparative examples were measured. In addition, the luminescent properties of the organic EL devices were evaluated using C9920-11 brightness light distribution characteristics measurement system of HAMAMATSU Photonics Co. Current density was measured at about 10 mA/cm². The results are shown in Table 1.

From the results shown in Table 1, it can be seen that the organic EL devices according to Examples 1 to 7 in which a hole transport layer (HTL) was formed using the monoamine derivative according to embodiments of the present disclosure had decreased driving voltage and improved emission efficiency when compared to those of the organic EL devices according to Comparative Examples 1 to 3.

For example, the organic EL devices according to Examples 1 to 7 in which the HTL was formed using the monoamine derivative according to embodiments of the present disclosure had a decreased driving voltage and improved emission efficiency when compared to those of the organic EL devices according to Comparative Examples 1 and 2, in which the HTLs were respectively formed using Comparative Compound C1 having a diamine structure (e.g., having two amine moieties) and Comparative Compound C2 in which one covalent bond forming a dibenzosilolyl ring (as in the monoamine derivative of Formula 1) is cleaved.

In addition, the organic EL devices according to Examples 1 to 7 in which the HTL was formed using the monoamine derivative according to embodiments of the present disclosure had a decreased driving voltage and improved emission efficiency when compared to those of the organic EL device according to Comparative Example 3, in which the HTL was formed using Comparative Compound C3 including a pyrenyl group instead of a dibenzosilolyl group. Since the pyrenyl group included in Comparative Compound C3 has high 7 electron conjugation, the energy gap of Comparative Compound C3 may decrease. Thus, the emission efficiency of the organic EL device according to Comparative Example 3, in which the HTL was formed using the Comparative Compound C3 may decrease.

As described above, the driving voltage of the organic EL device including the monoamine derivative according to embodiments of the present disclosure may decrease, and the emission efficiency thereof may be markedly improved in the regions from a blue emission region to a bluish green emission region.

When the material for an organic EL device includes the monoamine derivative represented by Formula 1 according to embodiments of the present disclosure, the organic EL device including the same may have a decreased driving voltage and significantly improved emission efficiency. Accordingly, the material for an organic EL device according to embodiments of the present disclosure may have various successful applications.

As described above, according to embodiments of the present disclosure, the driving voltage of an organic EL device including the material of embodiments of the present disclosure may be lowered, and the emission efficiency thereof may be improved.

Expressions such as “at least one of,” “one of,” “at least one selected from,” and “one selected from,” when preceding a list of elements, modify the entire list of elements and do not modify the individual elements of the list. Further, the use of “may” when describing embodiments of the present invention refers to “one or more embodiments of the present invention.”

In addition, as used herein, the terms “use,” “using,” and “used” may be considered synonymous with the terms “utilize,” “utilizing,” and “utilized,” respectively.

As used herein, the terms “substantially,” “about,” and similar terms are used as terms of approximation and not as terms of degree, and are intended to account for the inherent deviations in measured or calculated values that would be recognized by those of ordinary skill in the art.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112(a) and 35 U.S.C. §132(a).

The above-disclosed subject matter is to be considered illustrative and not restrictive, and the appended claims and equivalents thereof are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A material for an organic electroluminescent (EL) device, the material comprising a monoamine derivative represented by the following Formula 1: 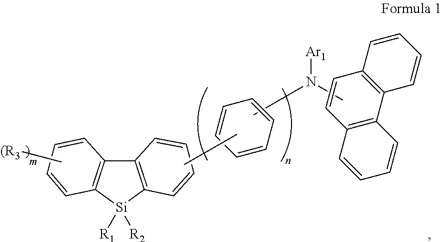
wherein Ar₁ is selected from a substituted or unsubstituted aryl group having 6 to 30 carbon atoms for forming a ring, and a substituted or unsubstituted heteroaryl group having 3 to 30 carbon atoms for forming a ring,
R₁ to R₃ are each independently selected from hydrogen, deuterium, a halogen atom, a substituted or unsubstituted alkyl group having 1 to 30 carbon atoms, a substituted or unsubstituted aryl group having 6 to 30 carbon atoms for forming a ring, and a substituted or unsubstituted heteroaryl group having 3 to 30 carbon atoms for forming a ring, and
n and m are each independently an integer selected from 0 to 4.

2. The material of claim 1, wherein Ar₁ is selected from a substituted or unsubstituted biphenyl group, a substituted or unsubstituted phenanthrenyl group, and a substituted or unsubstituted dibenzofuranyl group.

3. The material of claim 1, wherein the monoamine derivative comprises at least one compound selected from the following Compounds 1 to 48:

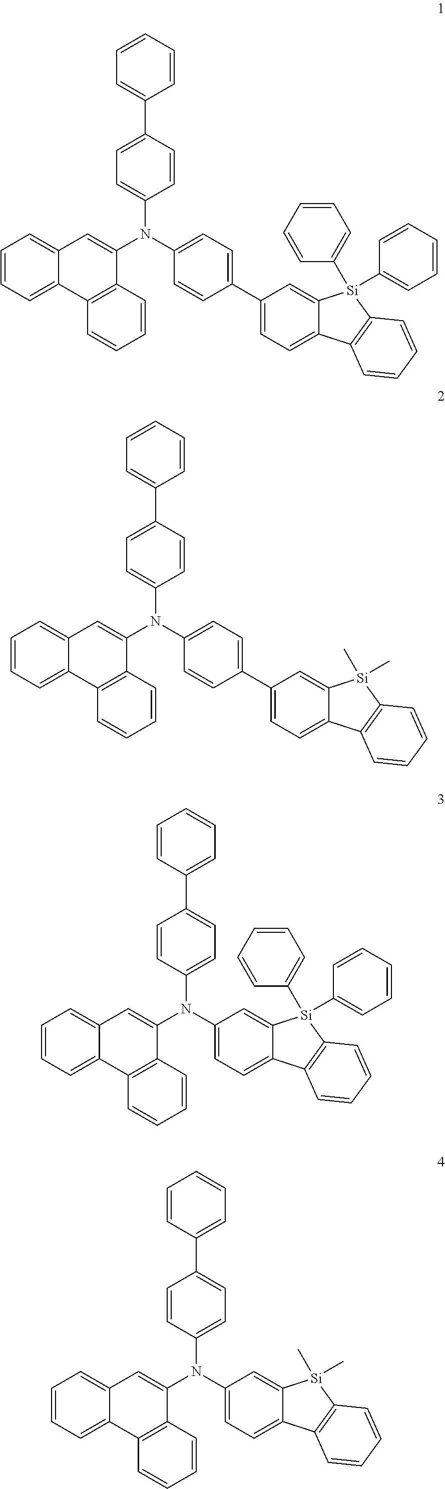 [SMILES: c1ccc(-c2ccc(N(c3ccc(-c4ccc5c(c4)[Si](c4ccccc4)(c4ccccc4)c4ccccc4-5)cc3)c3cc4ccccc4c4ccccc34)cc2)cc1 ; C[Si]1(C)c2ccccc2-c2ccc(-c3ccc(N(c4ccc(-c5ccccc5)cc4)c4cc5ccccc5c5ccccc45)cc3)cc21 ; c1ccc(-c2ccc(N(c3ccc4c(c3)[Si](c3ccccc3)(c3ccccc3)c3ccccc3-4)c3cc4ccccc4c4ccccc34)cc2)cc1 ; C[Si]1(C)c2ccccc2-c2ccc(N(c3ccc(-c4ccccc4)cc3)c3cc4ccccc4c4ccccc34)cc21]

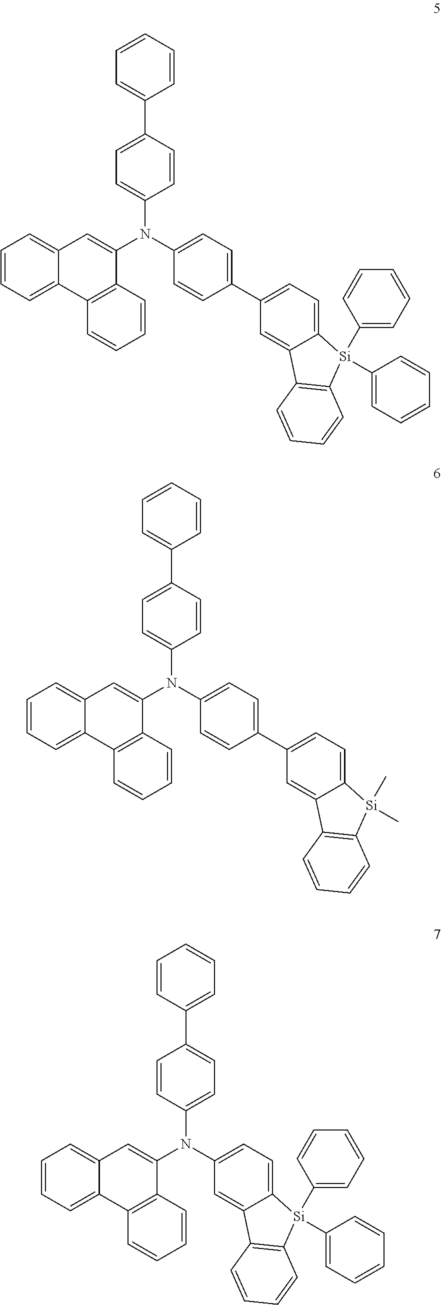 [SMILES: c1ccc(-c2ccc(N(c3ccc(-c4ccc5c(c4)-c4ccccc4[Si]5(c4ccccc4)c4ccccc4)cc3)c3cc4ccccc4c4ccccc34)cc2)cc1 ; C[Si]1(C)c2ccccc2-c2cc(-c3ccc(N(c4ccc(-c5ccccc5)cc4)c4cc5ccccc5c5ccccc45)cc3)ccc21 ; c1ccc(-c2ccc(N(c3ccc4c(c3)-c3ccccc3[Si]4(c3ccccc3)c3ccccc3)c3cc4ccccc4c4ccccc34)cc2)cc1]

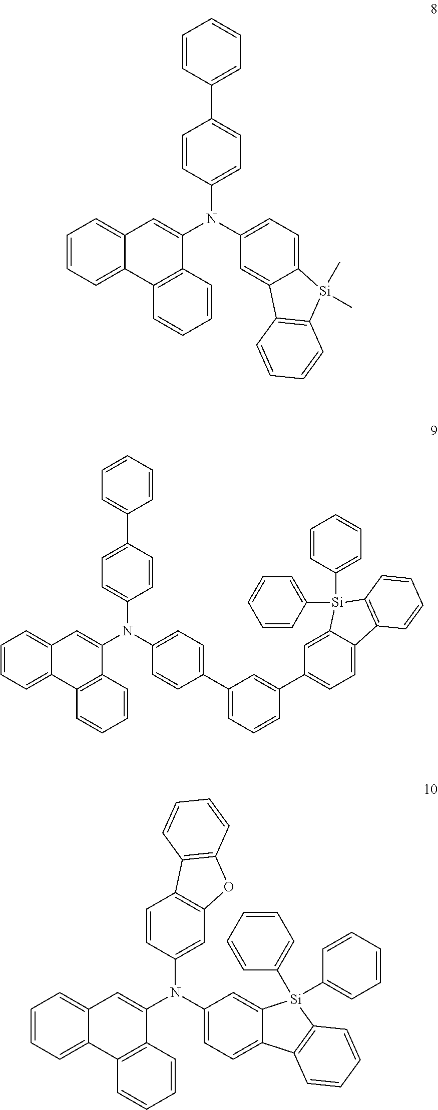 [SMILES: C[Si]1(C)c2ccccc2-c2cc(N(c3ccc(-c4ccccc4)cc3)c3cc4ccccc4c4ccccc34)ccc21 ; c1ccc(-c2ccc(N(c3ccc(-c4cccc(-c5ccc6c(c5)[Si](c5ccccc5)(c5ccccc5)c5ccccc5-6)c4)cc3)c3cc4ccccc4c4ccccc34)cc2)cc1 ; c1ccc([Si]2(c3ccccc3)c3ccccc3-c3ccc(N(c4ccc5c(c4)oc4ccccc45)c4cc5ccccc5c5ccccc45)cc32)cc1]

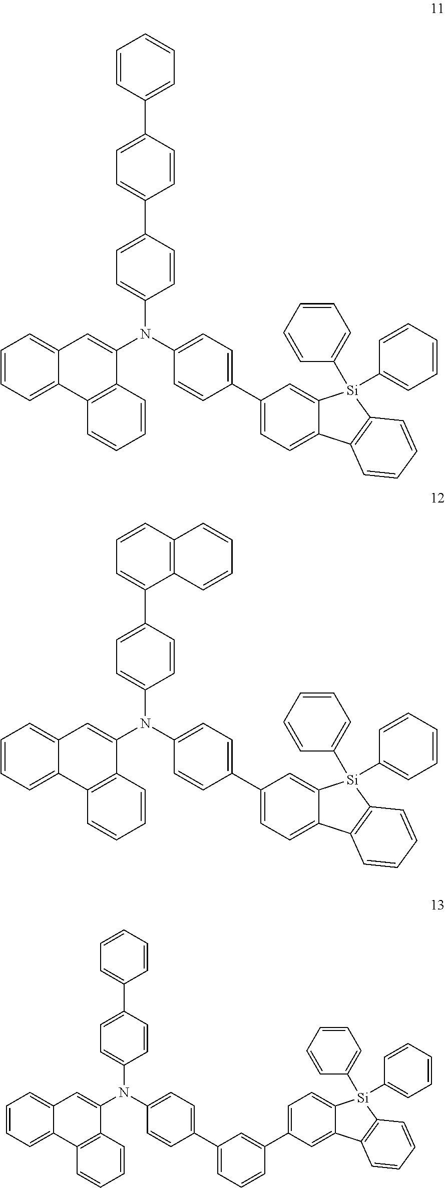 [SMILES: c1ccc(-c2ccc(-c3ccc(N(c4ccc(-c5ccc6c(c5)[Si](c5ccccc5)(c5ccccc5)c5ccccc5-6)cc4)c4cc5ccccc5c5ccccc45)cc3)cc2)cc1 ; c1ccc([Si]2(c3ccccc3)c3ccccc3-c3ccc(-c4ccc(N(c5ccc(-c6cccc7ccccc67)cc5)c5cc6ccccc6c6ccccc56)cc4)cc32)cc1 ; c1ccc(-c2ccc(N(c3ccc(-c4cccc(-c5ccc6c(c5)-c5ccccc5[Si]6(c5ccccc5)c5ccccc5)c4)cc3)c3cc4ccccc4c4ccccc34)cc2)cc1]

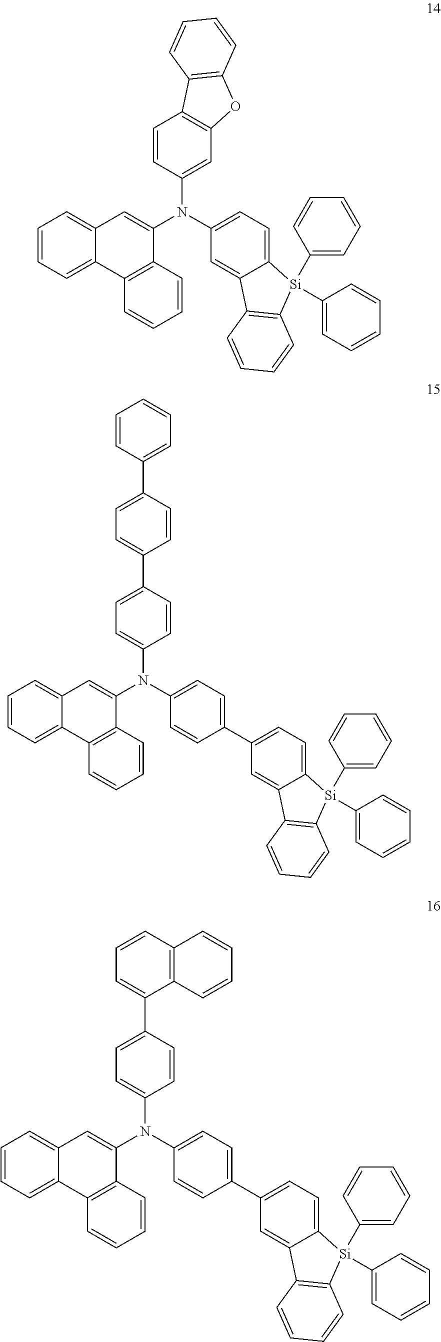 [SMILES: c1ccc([Si]2(c3ccccc3)c3ccccc3-c3cc(N(c4ccc5c(c4)oc4ccccc45)c4cc5ccccc5c5ccccc45)ccc32)cc1 ; c1ccc(-c2ccc(-c3ccc(N(c4ccc(-c5ccc6c(c5)-c5ccccc5[Si]6(c5ccccc5)c5ccccc5)cc4)c4cc5ccccc5c5ccccc45)cc3)cc2)cc1 ; c1ccc([Si]2(c3ccccc3)c3ccccc3-c3cc(-c4ccc(N(c5ccc(-c6cccc7ccccc67)cc5)c5cc6ccccc6c6ccccc56)cc4)ccc32)cc1]

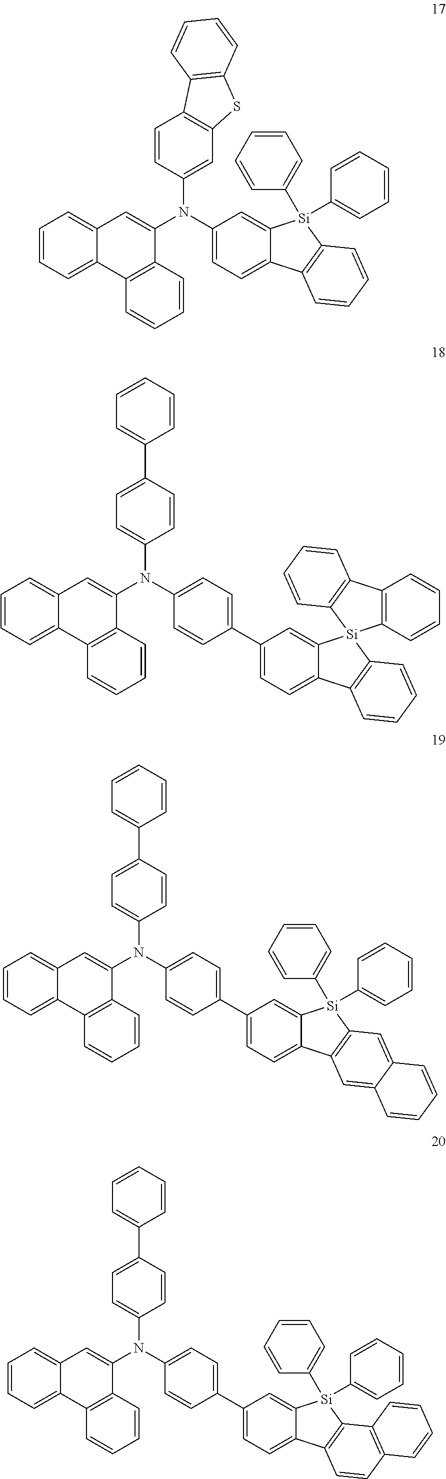 [SMILES: c1ccc([Si]2(c3ccccc3)c3ccccc3-c3ccc(N(c4ccc5c(c4)sc4ccccc45)c4cc5ccccc5c5ccccc45)cc32)cc1 ; c1ccc(-c2ccc(N(c3ccc(-c4ccc5c(c4)[Si]4(c6ccccc6-c6ccccc64)c4ccccc4-5)cc3)c3cc4ccccc4c4ccccc34)cc2)cc1 ; c1ccc(-c2ccc(N(c3ccc(-c4ccc5c(c4)[Si](c4ccccc4)(c4ccccc4)c4cc6ccccc6cc4-5)cc3)c3cc4ccccc4c4ccccc34)cc2)cc1 ; c1ccc(-c2ccc(N(c3ccc(-c4ccc5c(c4)[Si](c4ccccc4)(c4ccccc4)c4c-5ccc5ccccc45)cc3)c3cc4ccccc4c4ccccc34)cc2)cc1]

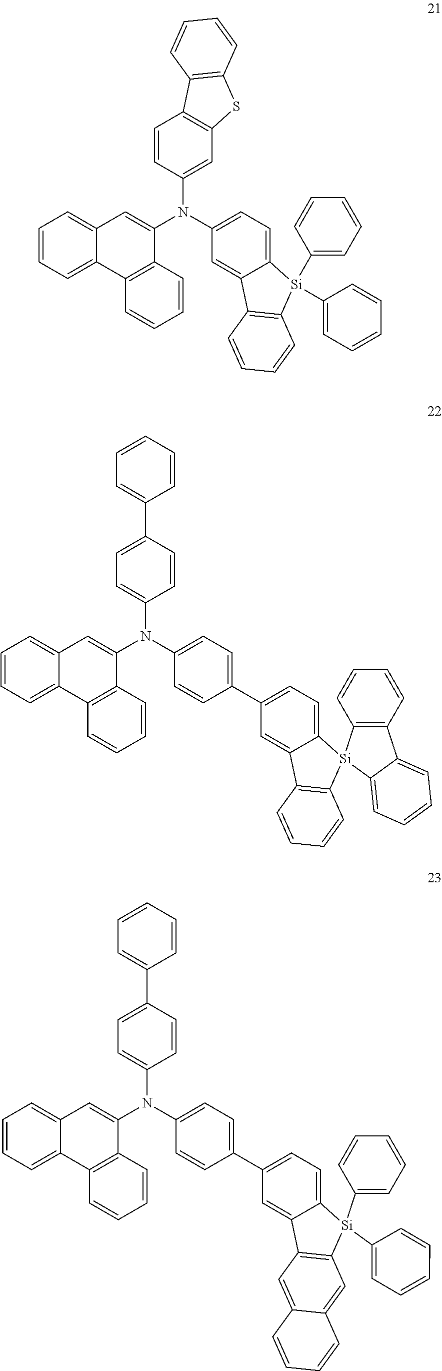 [SMILES: c1ccc([Si]2(c3ccccc3)c3ccccc3-c3cc(N(c4ccc5c(c4)sc4ccccc45)c4cc5ccccc5c5ccccc45)ccc32)cc1 ; c1ccc(-c2ccc(N(c3ccc(-c4ccc5c(c4)-c4ccccc4[Si]54c5ccccc5-c5ccccc54)cc3)c3cc4ccccc4c4ccccc34)cc2)cc1 ; c1ccc(-c2ccc(N(c3ccc(-c4ccc5c(c4)-c4cc6ccccc6cc4[Si]5(c4ccccc4)c4ccccc4)cc3)c3cc4ccccc4c4ccccc34)cc2)cc1]

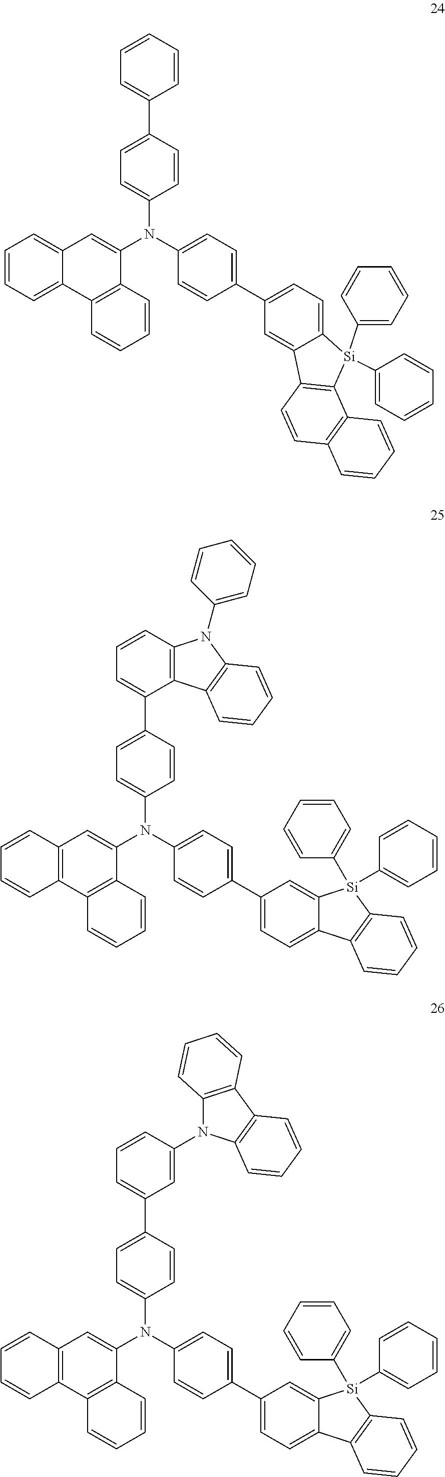 [SMILES: c1ccc(-c2ccc(N(c3ccc(-c4ccc5c(c4)-c4ccc6ccccc6c4[Si]5(c4ccccc4)c4ccccc4)cc3)c3cc4ccccc4c4ccccc34)cc2)cc1 ; c1ccc(-n2c3ccccc3c3c(-c4ccc(N(c5ccc(-c6ccc7c(c6)[Si](c6ccccc6)(c6ccccc6)c6ccccc6-7)cc5)c5cc6ccccc6c6ccccc56)cc4)cccc32)cc1 ; c1ccc([Si]2(c3ccccc3)c3ccccc3-c3ccc(-c4ccc(N(c5ccc(-c6cccc(-n7c8ccccc8c8ccccc87)c6)cc5)c5cc6ccccc6c6ccccc56)cc4)cc32)cc1]

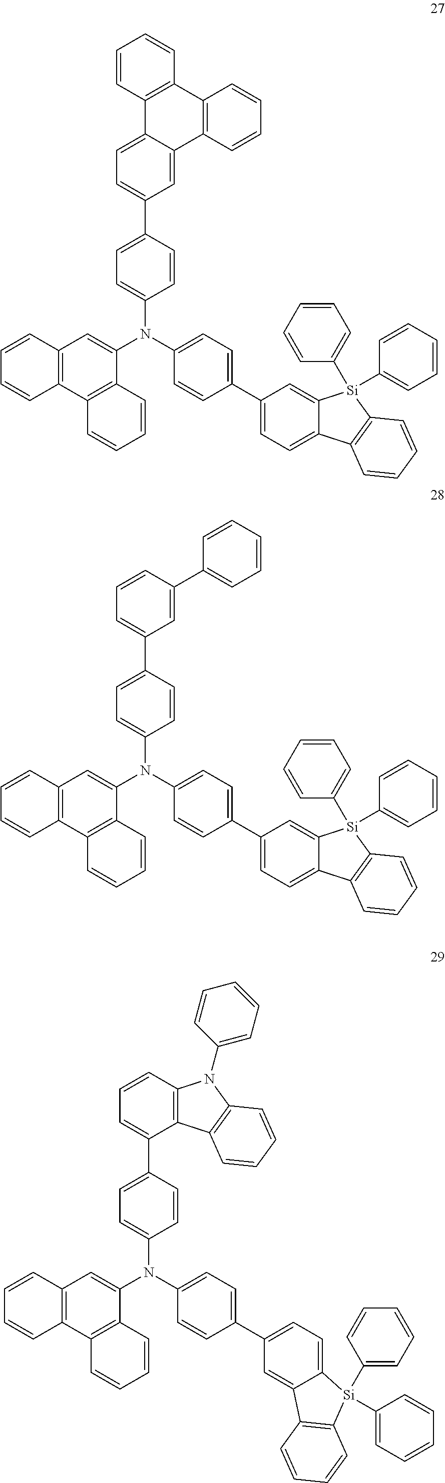 [SMILES: c1ccc([Si]2(c3ccccc3)c3ccccc3-c3ccc(-c4ccc(N(c5ccc(-c6ccc7c8ccccc8c8ccccc8c7c6)cc5)c5cc6ccccc6c6ccccc56)cc4)cc32)cc1 ; c1ccc(-c2cccc(-c3ccc(N(c4ccc(-c5ccc6c(c5)[Si](c5ccccc5)(c5ccccc5)c5ccccc5-6)cc4)c4cc5ccccc5c5ccccc45)cc3)c2)cc1 ; c1ccc(-n2c3ccccc3c3c(-c4ccc(N(c5ccc(-c6ccc7c(c6)-c6ccccc6[Si]7(c6ccccc6)c6ccccc6)cc5)c5cc6ccccc6c6ccccc56)cc4)cccc32)cc1]

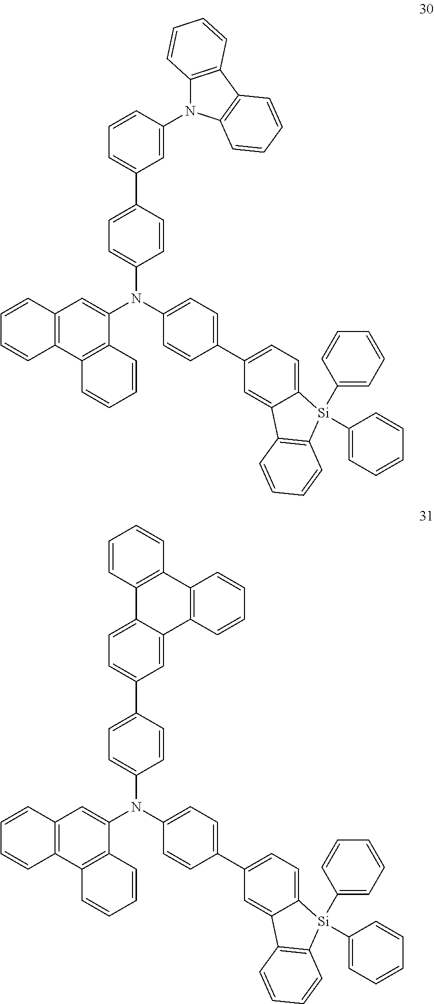 [SMILES: c1ccc([Si]2(c3ccccc3)c3ccccc3-c3cc(-c4ccc(N(c5ccc(-c6cccc(-n7c8ccccc8c8ccccc87)c6)cc5)c5cc6ccccc6c6ccccc56)cc4)ccc32)cc1 ; c1ccc([Si]2(c3ccccc3)c3ccccc3-c3cc(-c4ccc(N(c5ccc(-c6ccc7c8ccccc8c8ccccc8c7c6)cc5)c5cc6ccccc6c6ccccc56)cc4)ccc32)cc1]

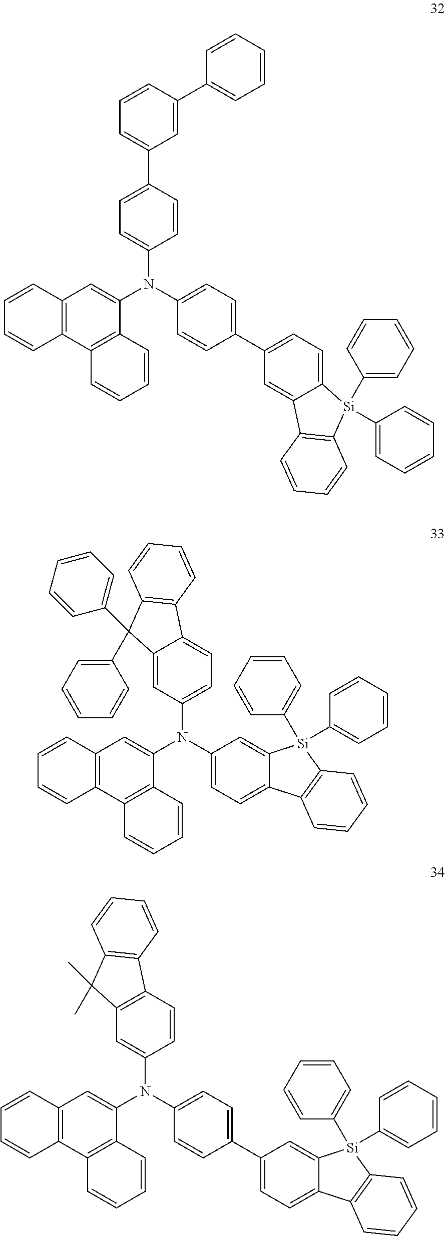 [SMILES: c1ccc(-c2cccc(-c3ccc(N(c4ccc(-c5ccc6c(c5)-c5ccccc5[Si]6(c5ccccc5)c5ccccc5)cc4)c4cc5ccccc5c5ccccc45)cc3)c2)cc1 ; c1ccc(C2(c3ccccc3)c3ccccc3-c3ccc(N(c4ccc5c(c4)[Si](c4ccccc4)(c4ccccc4)c4ccccc4-5)c4cc5ccccc5c5ccccc45)cc32)cc1 ; CC1(C)c2ccccc2-c2ccc(N(c3ccc(-c4ccc5c(c4)[Si](c4ccccc4)(c4ccccc4)c4ccccc4-5)cc3)c3cc4ccccc4c4ccccc34)cc21]

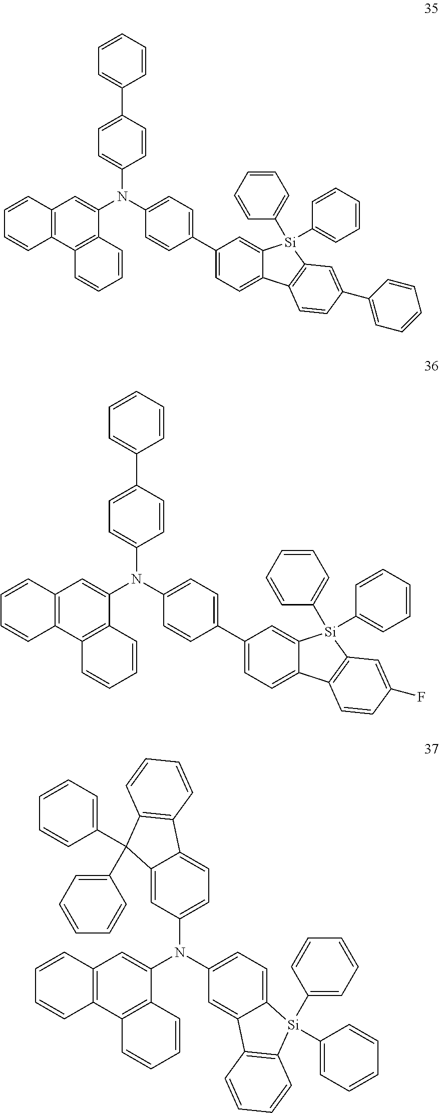 [SMILES: c1ccc(-c2ccc(N(c3ccc(-c4ccc5c(c4)[Si](c4ccccc4)(c4ccccc4)c4cc(-c6ccccc6)ccc4-5)cc3)c3cc4ccccc4c4ccccc34)cc2)cc1 ; Fc1ccc2c(c1)[Si](c1ccccc1)(c1ccccc1)c1cc(-c3ccc(N(c4ccc(-c5ccccc5)cc4)c4cc5ccccc5c5ccccc45)cc3)ccc1-2 ; c1ccc(C2(c3ccccc3)c3ccccc3-c3ccc(N(c4ccc5c(c4)-c4ccccc4[Si]5(c4ccccc4)c4ccccc4)c4cc5ccccc5c5ccccc45)cc32)cc1]

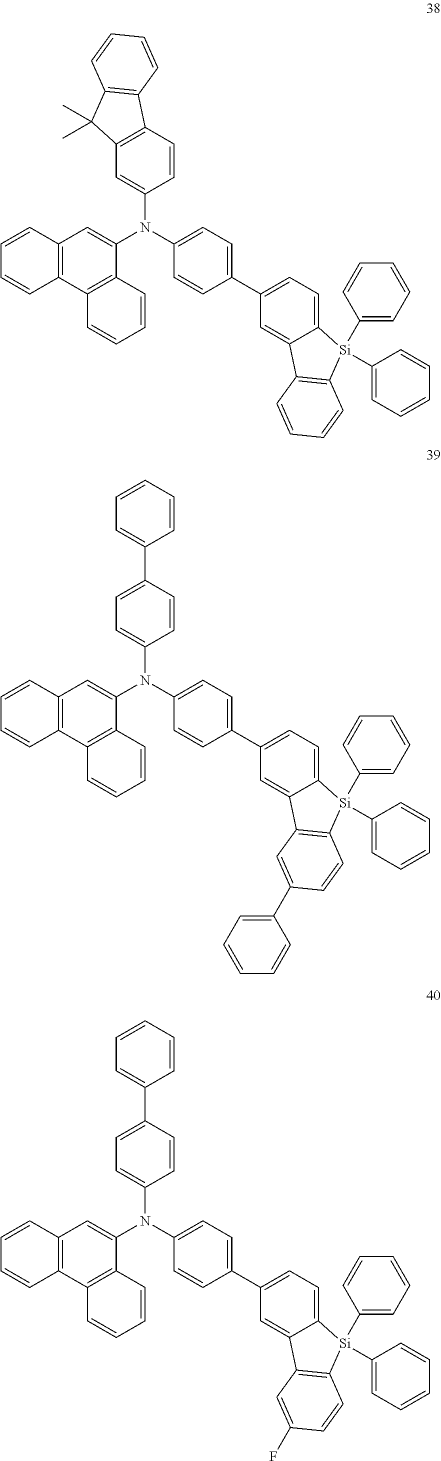 [SMILES: CC1(C)c2ccccc2-c2ccc(N(c3ccc(-c4ccc5c(c4)-c4ccccc4[Si]5(c4ccccc4)c4ccccc4)cc3)c3cc4ccccc4c4ccccc34)cc21 ; c1ccc(-c2ccc(N(c3ccc(-c4ccc5c(c4)-c4cc(-c6ccccc6)ccc4[Si]5(c4ccccc4)c4ccccc4)cc3)c3cc4ccccc4c4ccccc34)cc2)cc1 ; Fc1ccc2c(c1)-c1cc(-c3ccc(N(c4ccc(-c5ccccc5)cc4)c4cc5ccccc5c5ccccc45)cc3)ccc1[Si]2(c1ccccc1)c1ccccc1]

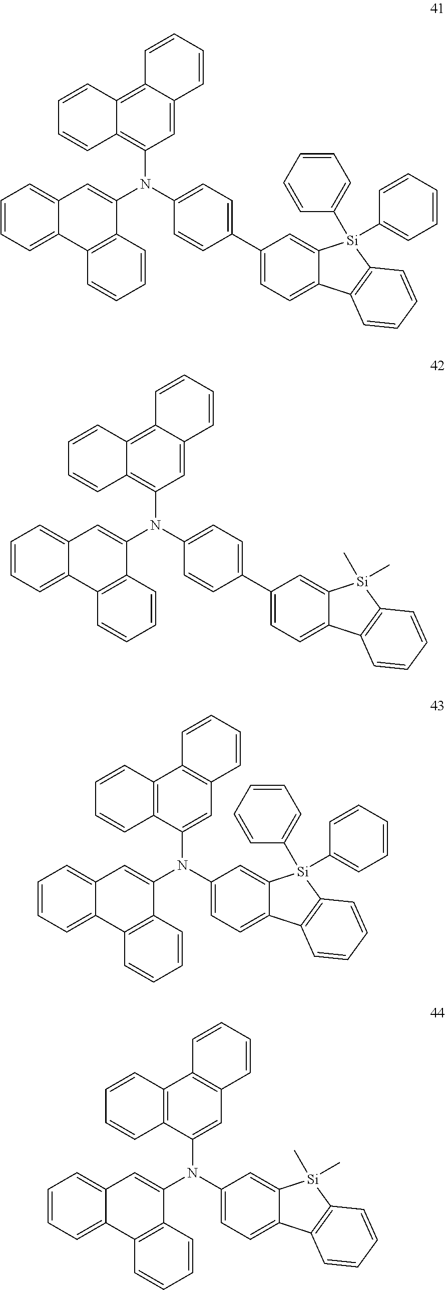 [SMILES: c1ccc([Si]2(c3ccccc3)c3ccccc3-c3ccc(-c4ccc(N(c5cc6ccccc6c6ccccc56)c5cc6ccccc6c6ccccc56)cc4)cc32)cc1 ; C[Si]1(C)c2ccccc2-c2ccc(-c3ccc(N(c4cc5ccccc5c5ccccc45)c4cc5ccccc5c5ccccc45)cc3)cc21 ; c1ccc([Si]2(c3ccccc3)c3ccccc3-c3ccc(N(c4cc5ccccc5c5ccccc45)c4cc5ccccc5c5ccccc45)cc32)cc1 ; C[Si]1(C)c2ccccc2-c2ccc(N(c3cc4ccccc4c4ccccc34)c3cc4ccccc4c4ccccc34)cc21]

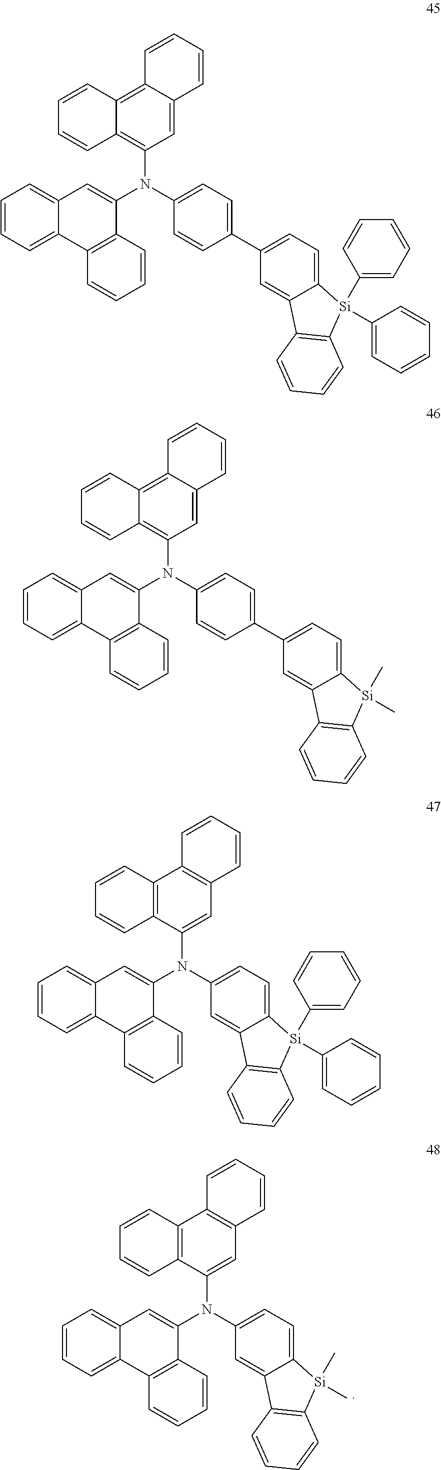

4. An organic electroluminescent (EL) device comprising:
an anode,
a cathode,
an emission layer between the anode and the cathode, and
at least one layer between the anode and the emission layer, the at least one layer comprising a material for an organic EL device,
wherein the material comprises a monoamine derivative represented by the following Formula 1: 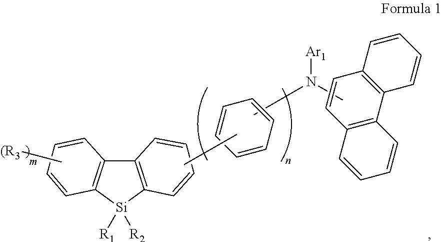
wherein Ar₁ is selected from a substituted or unsubstituted aryl group having 6 to 30 carbon atoms for forming a ring, and a substituted or unsubstituted heteroaryl group having 3 to 30 carbon atoms for forming a ring,
R₁ to R₃ are each independently selected from hydrogen, deuterium, a halogen atom, a substituted or unsubstituted alkyl group having 1 to 30 carbon atoms, a substituted or unsubstituted aryl group having 6 to 30 carbon atoms for forming a ring, and a substituted or unsubstituted heteroaryl group having 3 to 30 carbon atoms for forming a ring, and
n and m are each independently an integer selected from 0 to 4.

5. The organic EL device of claim 4, wherein Ar₁ is selected from a substituted or unsubstituted biphenyl group, a substituted or unsubstituted phenanthrenyl group, and a substituted or unsubstituted dibenzofuranyl group.

6. The organic EL device of claim 4, wherein the monoamine derivative comprises at least one compound selected from the following Compounds 1 to 48:

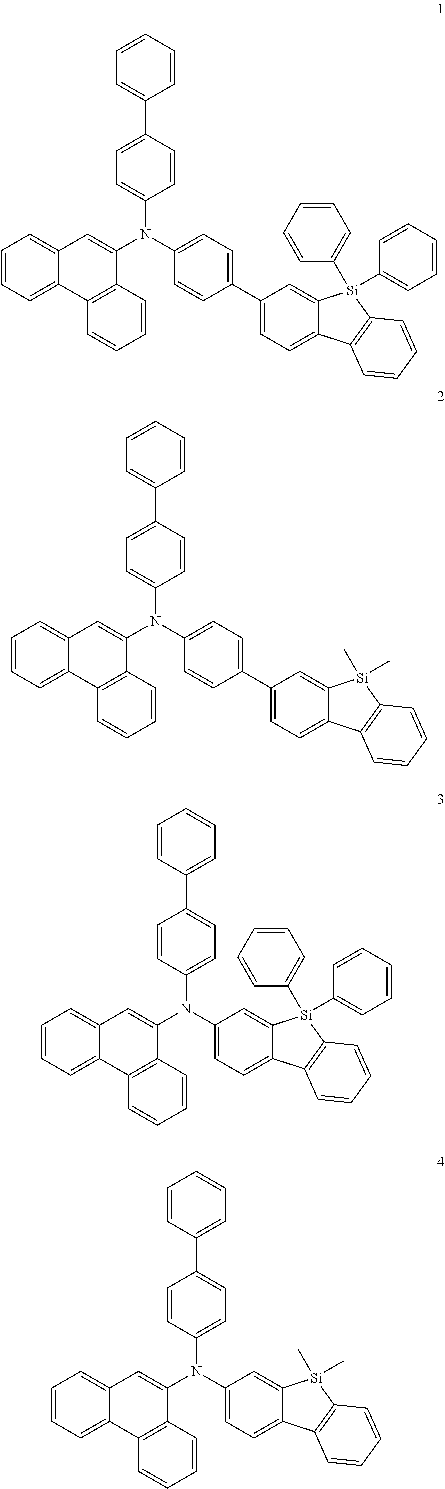 [SMILES: c1ccc(-c2ccc(N(c3ccc(-c4ccc5c(c4)[Si](c4ccccc4)(c4ccccc4)c4ccccc4-5)cc3)c3cc4ccccc4c4ccccc34)cc2)cc1 ; C[Si]1(C)c2ccccc2-c2ccc(-c3ccc(N(c4ccc(-c5ccccc5)cc4)c4cc5ccccc5c5ccccc45)cc3)cc21 ; c1ccc(-c2ccc(N(c3ccc4c(c3)[Si](c3ccccc3)(c3ccccc3)c3ccccc3-4)c3cc4ccccc4c4ccccc34)cc2)cc1 ; C[Si]1(C)c2ccccc2-c2ccc(N(c3ccc(-c4ccccc4)cc3)c3cc4ccccc4c4ccccc34)cc21]

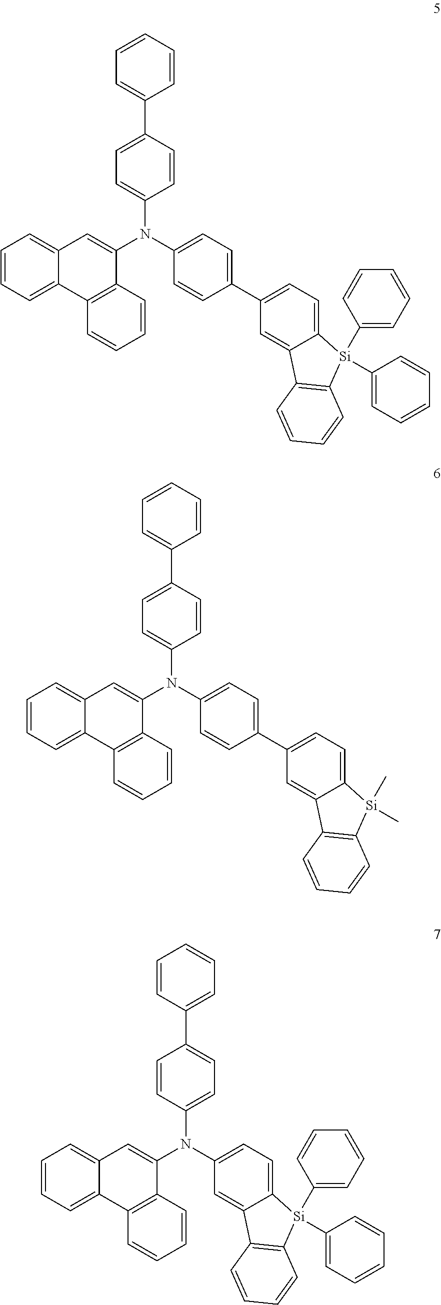 [SMILES: c1ccc(-c2ccc(N(c3ccc(-c4ccc5c(c4)-c4ccccc4[Si]5(c4ccccc4)c4ccccc4)cc3)c3cc4ccccc4c4ccccc34)cc2)cc1 ; C[Si]1(C)c2ccccc2-c2cc(-c3ccc(N(c4ccc(-c5ccccc5)cc4)c4cc5ccccc5c5ccccc45)cc3)ccc21 ; c1ccc(-c2ccc(N(c3ccc4c(c3)-c3ccccc3[Si]4(c3ccccc3)c3ccccc3)c3cc4ccccc4c4ccccc34)cc2)cc1]

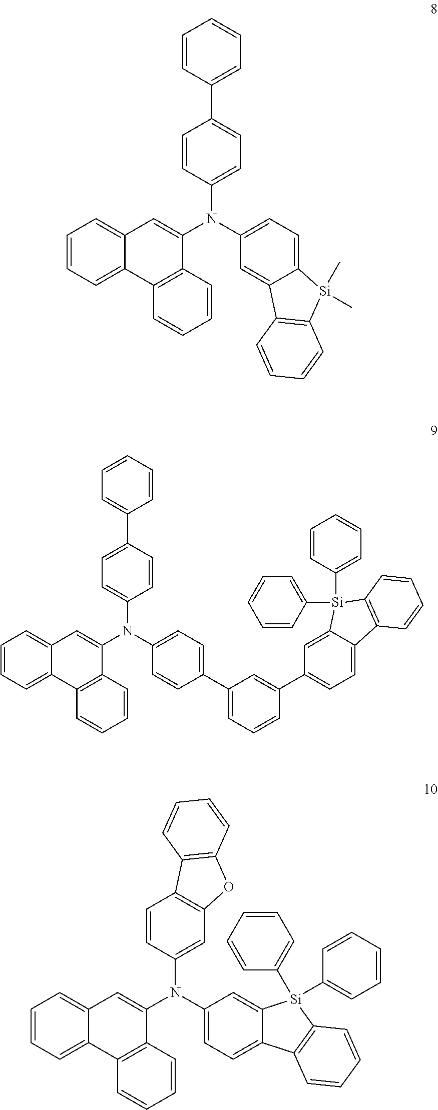 [SMILES: C[Si]1(C)c2ccccc2-c2cc(N(c3ccc(-c4ccccc4)cc3)c3cc4ccccc4c4ccccc34)ccc21 ; c1ccc(-c2ccc(N(c3ccc(-c4cccc(-c5ccc6c(c5)[Si](c5ccccc5)(c5ccccc5)c5ccccc5-6)c4)cc3)c3cc4ccccc4c4ccccc34)cc2)cc1 ; c1ccc([Si]2(c3ccccc3)c3ccccc3-c3ccc(N(c4ccc5c(c4)oc4ccccc45)c4cc5ccccc5c5ccccc45)cc32)cc1]

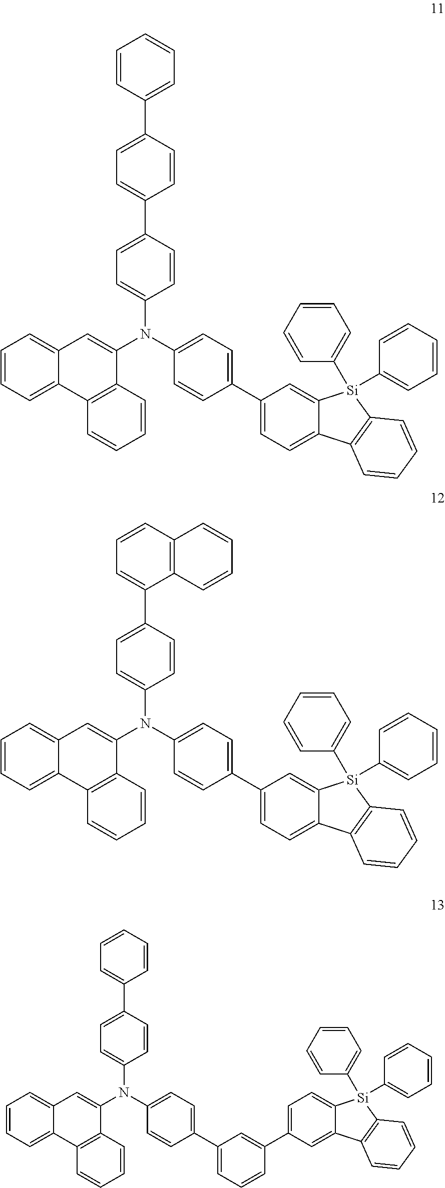 [SMILES: c1ccc(-c2ccc(-c3ccc(N(c4ccc(-c5ccc6c(c5)[Si](c5ccccc5)(c5ccccc5)c5ccccc5-6)cc4)c4cc5ccccc5c5ccccc45)cc3)cc2)cc1 ; c1ccc([Si]2(c3ccccc3)c3ccccc3-c3ccc(-c4ccc(N(c5ccc(-c6cccc7ccccc67)cc5)c5cc6ccccc6c6ccccc56)cc4)cc32)cc1 ; c1ccc(-c2ccc(N(c3ccc(-c4cccc(-c5ccc6c(c5)-c5ccccc5[Si]6(c5ccccc5)c5ccccc5)c4)cc3)c3cc4ccccc4c4ccccc34)cc2)cc1]

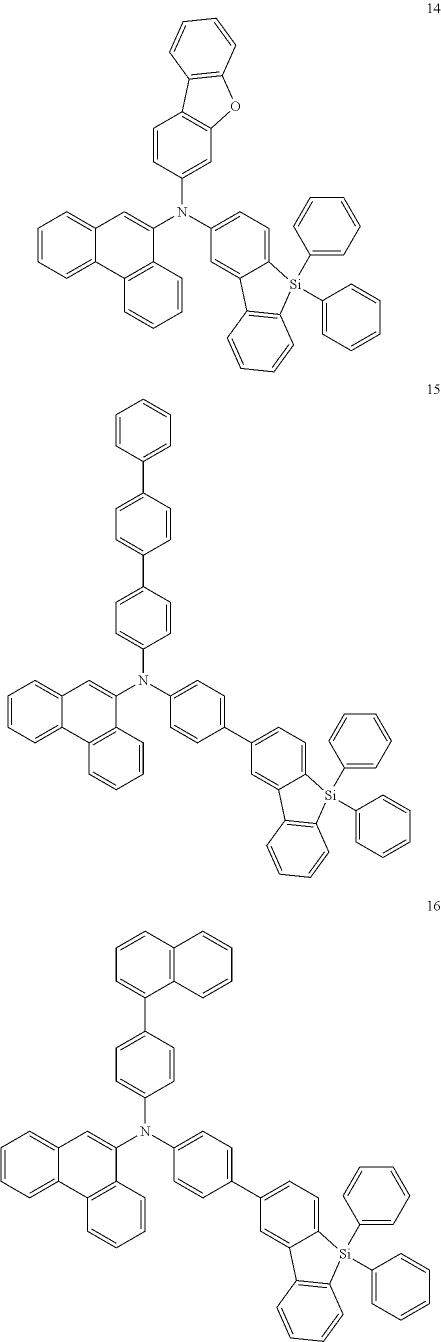 [SMILES: c1ccc([Si]2(c3ccccc3)c3ccccc3-c3cc(N(c4ccc5c(c4)oc4ccccc45)c4cc5ccccc5c5ccccc45)ccc32)cc1 ; c1ccc(-c2ccc(-c3ccc(N(c4ccc(-c5ccc6c(c5)-c5ccccc5[Si]6(c5ccccc5)c5ccccc5)cc4)c4cc5ccccc5c5ccccc45)cc3)cc2)cc1 ; c1ccc([Si]2(c3ccccc3)c3ccccc3-c3cc(-c4ccc(N(c5ccc(-c6cccc7ccccc67)cc5)c5cc6ccccc6c6ccccc56)cc4)ccc32)cc1]

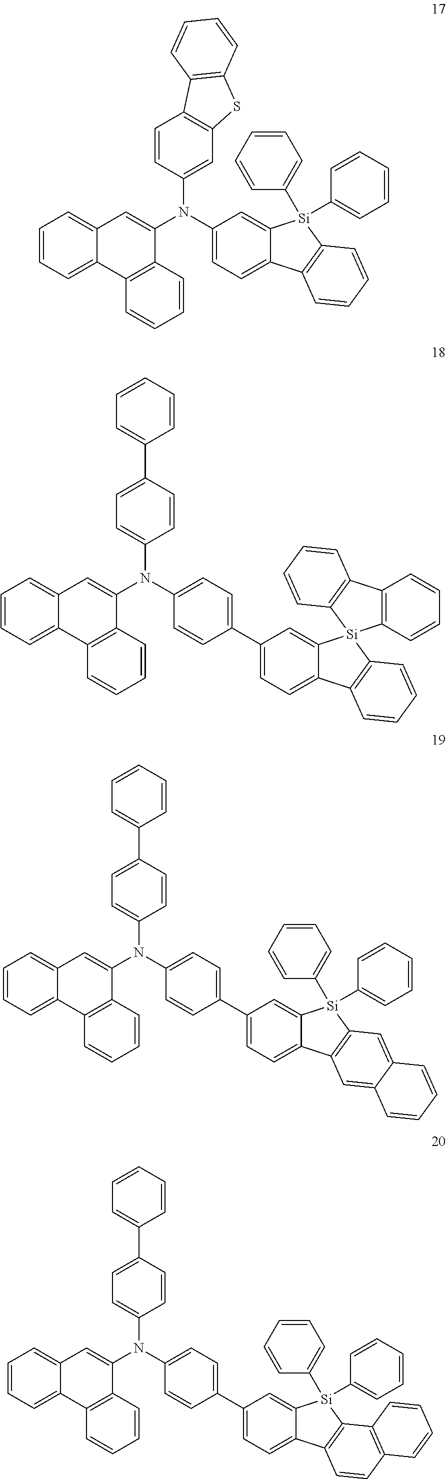 [SMILES: c1ccc([Si]2(c3ccccc3)c3ccccc3-c3ccc(N(c4ccc5c(c4)sc4ccccc45)c4cc5ccccc5c5ccccc45)cc32)cc1 ; c1ccc(-c2ccc(N(c3ccc(-c4ccc5c(c4)[Si]4(c6ccccc6-c6ccccc64)c4ccccc4-5)cc3)c3cc4ccccc4c4ccccc34)cc2)cc1 ; c1ccc(-c2ccc(N(c3ccc(-c4ccc5c(c4)[Si](c4ccccc4)(c4ccccc4)c4cc6ccccc6cc4-5)cc3)c3cc4ccccc4c4ccccc34)cc2)cc1 ; c1ccc(-c2ccc(N(c3ccc(-c4ccc5c(c4)[Si](c4ccccc4)(c4ccccc4)c4c-5ccc5ccccc45)cc3)c3cc4ccccc4c4ccccc34)cc2)cc1]

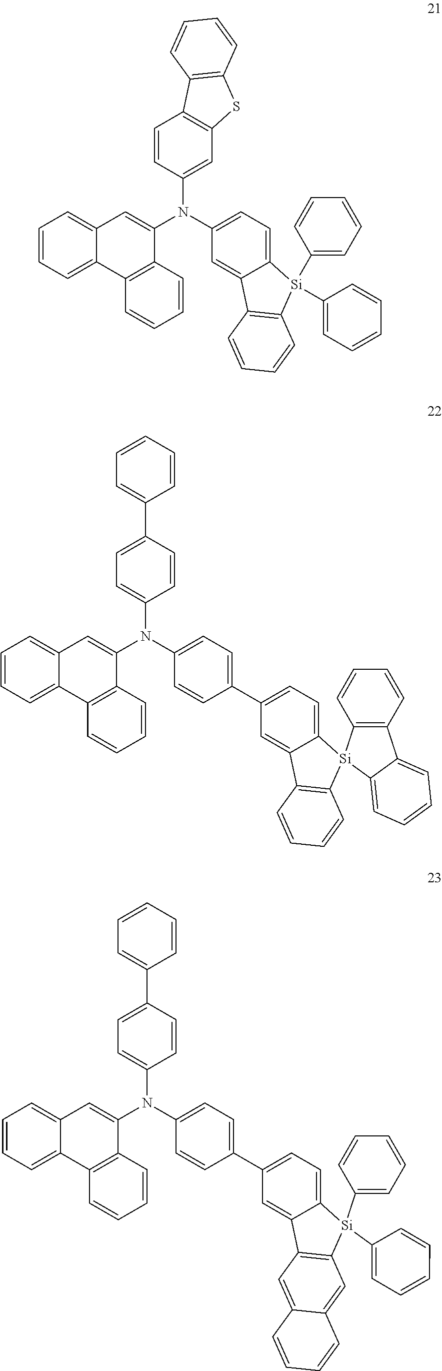 [SMILES: c1ccc([Si]2(c3ccccc3)c3ccccc3-c3cc(N(c4ccc5c(c4)sc4ccccc45)c4cc5ccccc5c5ccccc45)ccc32)cc1 ; c1ccc(-c2ccc(N(c3ccc(-c4ccc5c(c4)-c4ccccc4[Si]54c5ccccc5-c5ccccc54)cc3)c3cc4ccccc4c4ccccc34)cc2)cc1 ; c1ccc(-c2ccc(N(c3ccc(-c4ccc5c(c4)-c4cc6ccccc6cc4[Si]5(c4ccccc4)c4ccccc4)cc3)c3cc4ccccc4c4ccccc34)cc2)cc1]

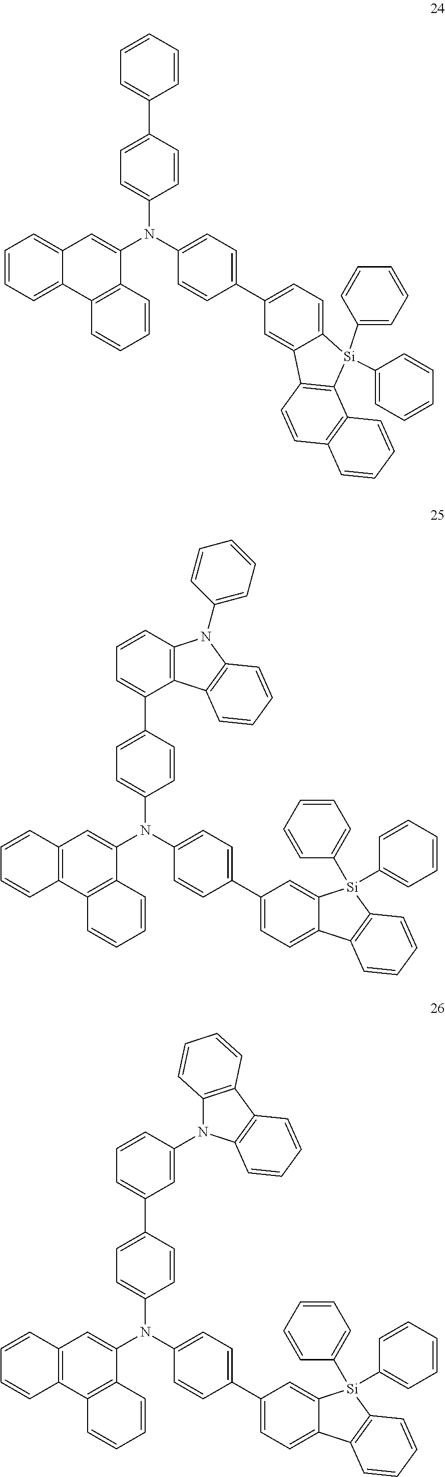 [SMILES: c1ccc(-c2ccc(N(c3ccc(-c4ccc5c(c4)-c4ccc6ccccc6c4[Si]5(c4ccccc4)c4ccccc4)cc3)c3cc4ccccc4c4ccccc34)cc2)cc1 ; c1ccc(-n2c3ccccc3c3c(-c4ccc(N(c5ccc(-c6ccc7c(c6)[Si](c6ccccc6)(c6ccccc6)c6ccccc6-7)cc5)c5cc6ccccc6c6ccccc56)cc4)cccc32)cc1 ; c1ccc([Si]2(c3ccccc3)c3ccccc3-c3ccc(-c4ccc(N(c5ccc(-c6cccc(-n7c8ccccc8c8ccccc87)c6)cc5)c5cc6ccccc6c6ccccc56)cc4)cc32)cc1]

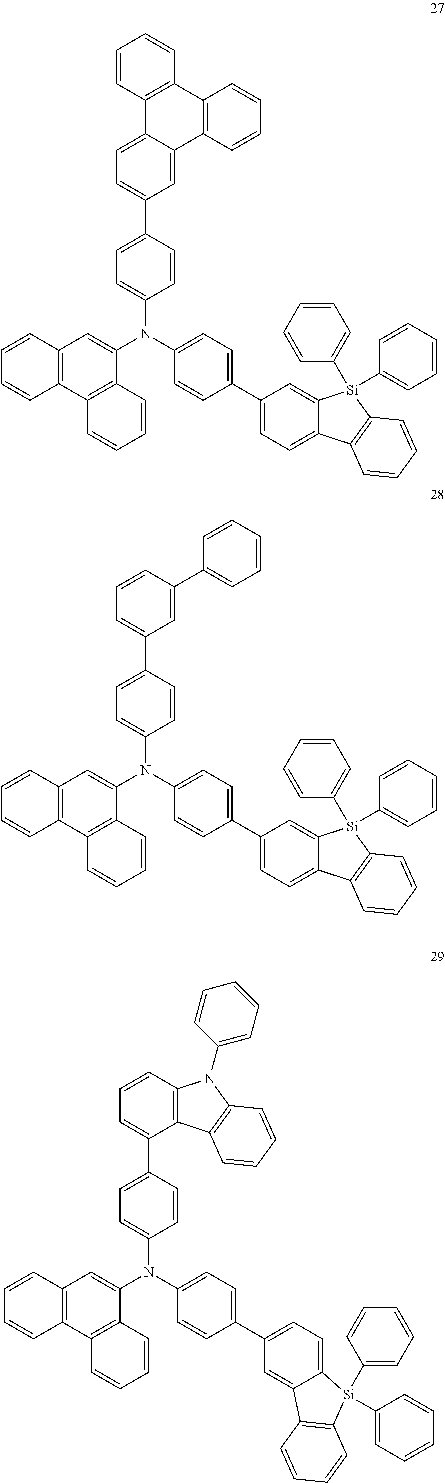 [SMILES: c1ccc([Si]2(c3ccccc3)c3ccccc3-c3ccc(-c4ccc(N(c5ccc(-c6ccc7c8ccccc8c8ccccc8c7c6)cc5)c5cc6ccccc6c6ccccc56)cc4)cc32)cc1 ; c1ccc(-c2cccc(-c3ccc(N(c4ccc(-c5ccc6c(c5)[Si](c5ccccc5)(c5ccccc5)c5ccccc5-6)cc4)c4cc5ccccc5c5ccccc45)cc3)c2)cc1 ; c1ccc(-n2c3ccccc3c3c(-c4ccc(N(c5ccc(-c6ccc7c(c6)-c6ccccc6[Si]7(c6ccccc6)c6ccccc6)cc5)c5cc6ccccc6c6ccccc56)cc4)cccc32)cc1]

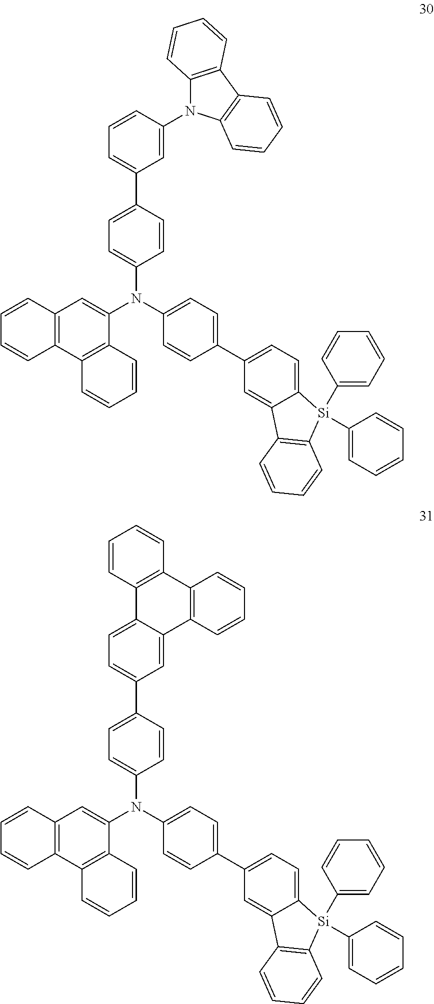 [SMILES: c1ccc([Si]2(c3ccccc3)c3ccccc3-c3cc(-c4ccc(N(c5ccc(-c6cccc(-n7c8ccccc8c8ccccc87)c6)cc5)c5cc6ccccc6c6ccccc56)cc4)ccc32)cc1 ; c1ccc([Si]2(c3ccccc3)c3ccccc3-c3cc(-c4ccc(N(c5ccc(-c6ccc7c8ccccc8c8ccccc8c7c6)cc5)c5cc6ccccc6c6ccccc56)cc4)ccc32)cc1]

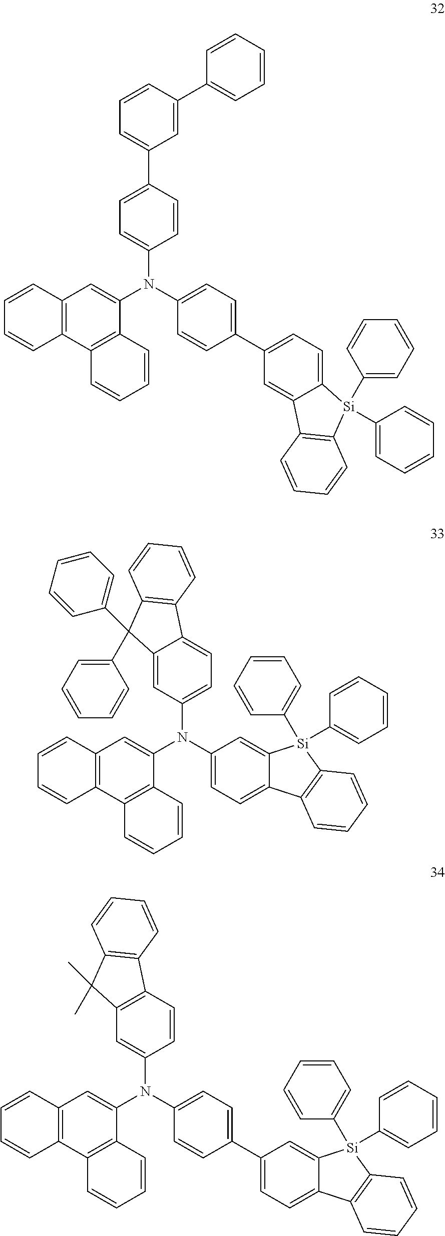 [SMILES: c1ccc(-c2cccc(-c3ccc(N(c4ccc(-c5ccc6c(c5)-c5ccccc5[Si]6(c5ccccc5)c5ccccc5)cc4)c4cc5ccccc5c5ccccc45)cc3)c2)cc1 ; c1ccc(C2(c3ccccc3)c3ccccc3-c3ccc(N(c4ccc5c(c4)[Si](c4ccccc4)(c4ccccc4)c4ccccc4-5)c4cc5ccccc5c5ccccc45)cc32)cc1 ; CC1(C)c2ccccc2-c2ccc(N(c3ccc(-c4ccc5c(c4)[Si](c4ccccc4)(c4ccccc4)c4ccccc4-5)cc3)c3cc4ccccc4c4ccccc34)cc21]

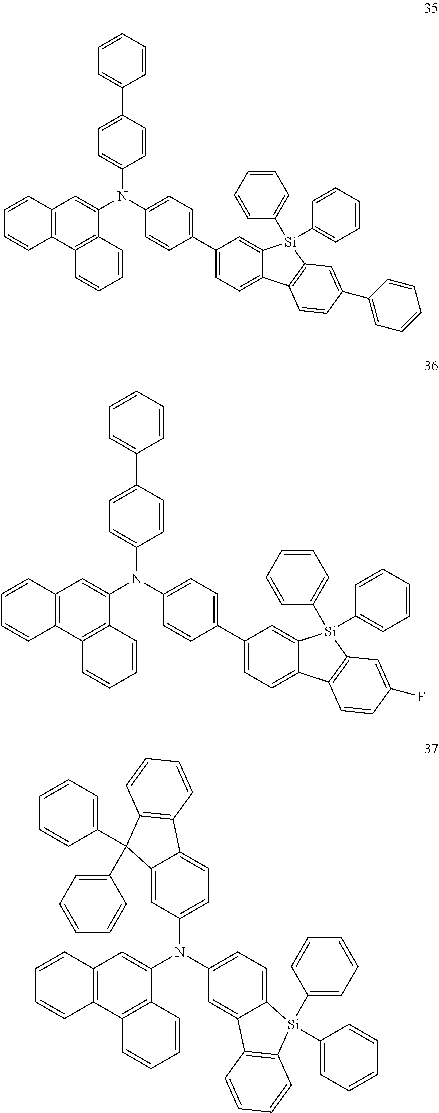 [SMILES: c1ccc(-c2ccc(N(c3ccc(-c4ccc5c(c4)[Si](c4ccccc4)(c4ccccc4)c4cc(-c6ccccc6)ccc4-5)cc3)c3cc4ccccc4c4ccccc34)cc2)cc1 ; Fc1ccc2c(c1)[Si](c1ccccc1)(c1ccccc1)c1cc(-c3ccc(N(c4ccc(-c5ccccc5)cc4)c4cc5ccccc5c5ccccc45)cc3)ccc1-2 ; c1ccc(C2(c3ccccc3)c3ccccc3-c3ccc(N(c4ccc5c(c4)-c4ccccc4[Si]5(c4ccccc4)c4ccccc4)c4cc5ccccc5c5ccccc45)cc32)cc1]

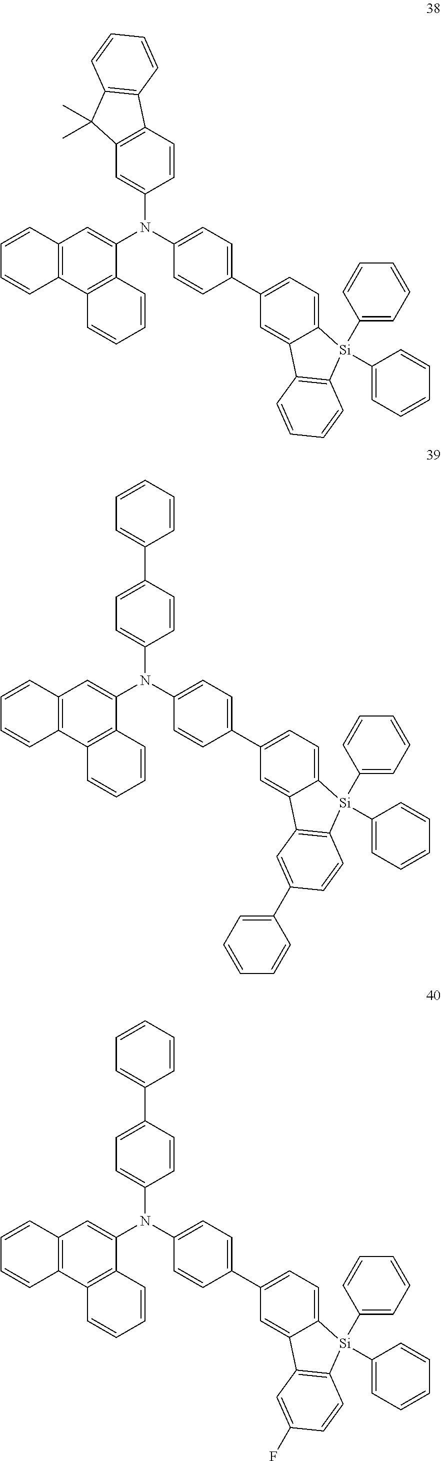 [SMILES: CC1(C)c2ccccc2-c2ccc(N(c3ccc(-c4ccc5c(c4)-c4ccccc4[Si]5(c4ccccc4)c4ccccc4)cc3)c3cc4ccccc4c4ccccc34)cc21 ; c1ccc(-c2ccc(N(c3ccc(-c4ccc5c(c4)-c4cc(-c6ccccc6)ccc4[Si]5(c4ccccc4)c4ccccc4)cc3)c3cc4ccccc4c4ccccc34)cc2)cc1 ; Fc1ccc2c(c1)-c1cc(-c3ccc(N(c4ccc(-c5ccccc5)cc4)c4cc5ccccc5c5ccccc45)cc3)ccc1[Si]2(c1ccccc1)c1ccccc1]

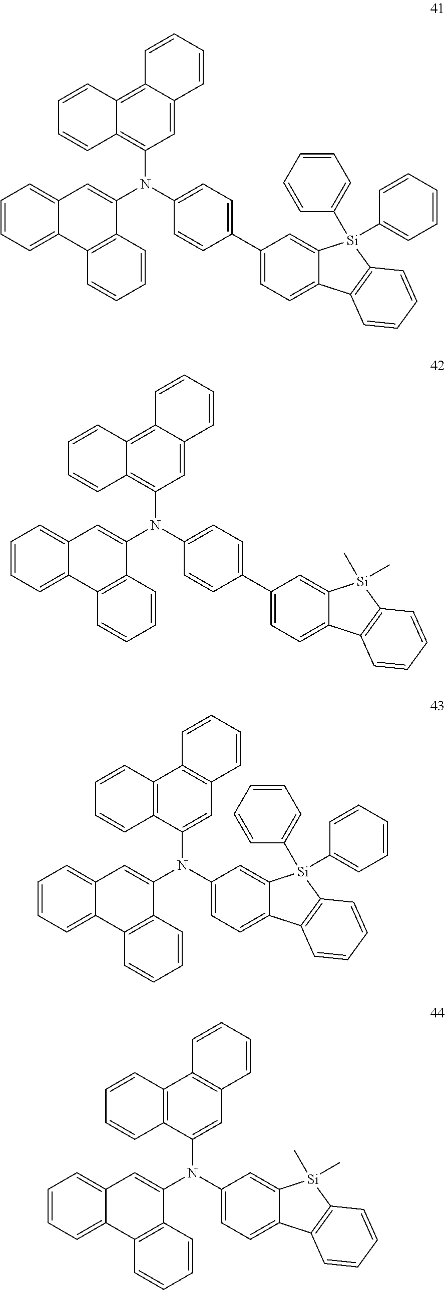 [SMILES: c1ccc([Si]2(c3ccccc3)c3ccccc3-c3ccc(-c4ccc(N(c5cc6ccccc6c6ccccc56)c5cc6ccccc6c6ccccc56)cc4)cc32)cc1 ; C[Si]1(C)c2ccccc2-c2ccc(-c3ccc(N(c4cc5ccccc5c5ccccc45)c4cc5ccccc5c5ccccc45)cc3)cc21 ; c1ccc([Si]2(c3ccccc3)c3ccccc3-c3ccc(N(c4cc5ccccc5c5ccccc45)c4cc5ccccc5c5ccccc45)cc32)cc1 ; C[Si]1(C)c2ccccc2-c2ccc(N(c3cc4ccccc4c4ccccc34)c3cc4ccccc4c4ccccc34)cc21]

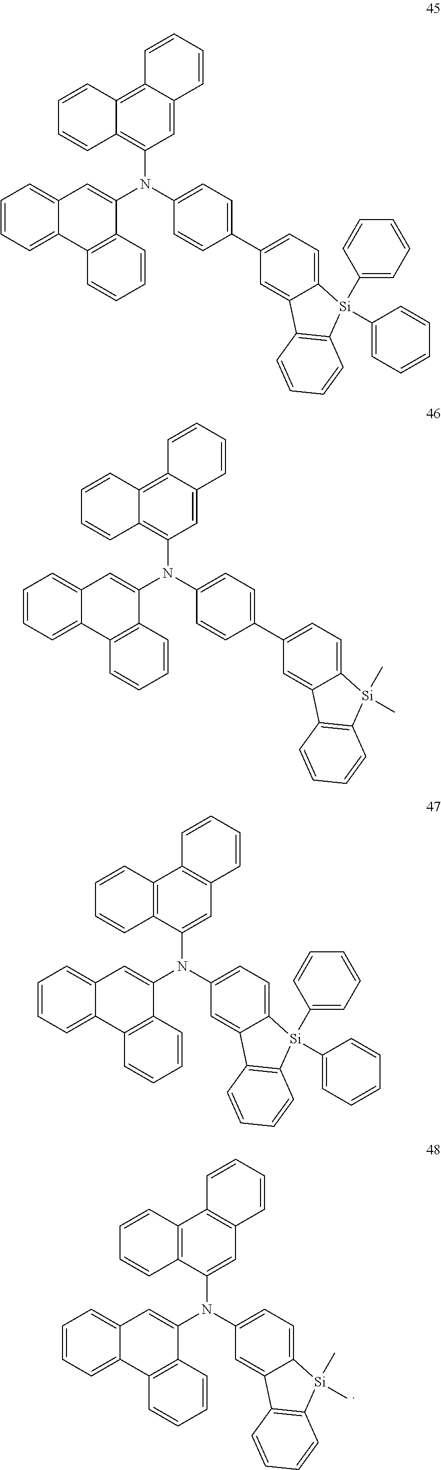

7. The organic EL device of claim 4, wherein the material is comprised in the layer more adjacent to the emission layer than the anode.
